(19) United States
(12) Patent Application Publication
(10) Pub. No.: US 2024/0094261 A1
(43) Pub. Date: Mar. 21, 2024

(54) Probe Arrays and Improved Methods for Making and Using Longitudinal Deformation of Probe Preforms

(71) Applicant: Microfabrica Inc., Van Nuys, CA (US)

(72) Inventors: Michael S. Lockard, Lake Elizabeth, CA (US); Uri Frodis, Los Angeles, CA (US); Dennis R. Smalley, Newhall, CA (US)

(73) Assignee: Microfabrica Inc., Van Nuys, CA (US)

(21) Appl. No.: 17/401,252

(22) Filed: Aug. 12, 2021

Related U.S. Application Data
(60) Provisional application No. 63/064,888, filed on Aug. 12, 2020.

(51) Int. Cl. G01R 3/00; G01R 1/067

(52) U.S. Cl. CPC G01R 3/00; G01R 1/06722; G01R 1/06761

(57) ABSTRACT

Probes for testing (e.g. wafer level testing or socket level testing) of electronic devices (e.g. semiconductor devices) and more particularly, arrays of such probes are provided. Probes are formed by initially fabricating probe preforms in batch with bases and/or ends located in array patterns, directly or indirectly on one or more build substrates with the arrayed preforms being in a longitudinally compressed state and whereafter the preforms are longitudinally plastically deformed to yield probes or partially formed probes with extended longitudinal lengths. Probes may be formed with deformable spring elements formed from one or more single layers which are joined by vertical elements located on other layers or they may be formed by spring elements that are formed as multi-layer structures. Arrays may include probe preforms with laterally overlapping or interlaced structures (but longitudinally displaced) which may remain laterally overlapping or become laterally displaced upon plastic deformation.

### RELATED APPLICATIONS

This application claims the benefit of U.S. Provisional Patent Application No. 63/064,888, filed Aug. 12, 2020. This referenced application is incorporated herein by reference as if set forth in full herein.

### FIELD OF THE INVENTION

The present disclosure relates generally to the field of probes for testing (e.g. wafer level testing or socket level testing) of electronic devices (e.g. semiconductor devices) and more particularly to arrays of such probes, wherein probe preforms may be fabricated in batch with bases and/or ends located in array configuration, directly or indirectly on one or more build substrates where the preforms are longitudinally compressed relative to the final longitudinal extent of the probes or probe portions that are to be formed from the preforms and whereafter the preforms are longitudinally plastically deformed via bending and or stretching to yield probes or partially formed probes with an extended longitudinal length (compared to initial state of the preforms).

### BACKGROUND OF THE INVENTION

### Probes:

Probes of various types have been fabricated and used or have been proposed for use in semiconductor testing. As the semiconductor industry continues to drive integrated circuit complexity up and size down (more transistors per unit area), a need exists for new and improved probe arrays, methods of making such probe arrays, probe designs for use in such arrays, and/or methods of making such probes where the arrays and probes are used either for testing purposes and associated temporary contact and/or for making permanent contact with such devices. This need drives probes to smaller sizes (e.g. smaller X and Y cross-sectional or lateral dimensions and sometimes to shorter lengths, or longitudinal dimensions, in Z), lower contact force, less scrubbing or more controlled scrubbing, while still maintaining high current carrying capacity so that shorts in failed semiconductor devices do not damage the probes. This need further drives arrays of such probes to finer pitches (i.e. smaller nominal spacing between adjacent probes and probe tips). A need exists for improved probes, probe arrays, and methods of making such probes and arrays to meet the new challenges that the semiconductor industry is driving.

Numerous electrical contact probe and pin configurations as well as array formation methods have been commercially used or proposed, some of which may be prior art while others are not. Examples of such pins, probes, arrays, and methods of making are set forth in the following patent applications, publications of applications, and patents. Each of these applications, publications, and patents is incorporated herein by reference as if set forth in full herein.

| U.S. Pat App No., Filing Date | |
|---|---|
| U.S. App Pub No., Pub Date | |
| U.S. Patent No., Pub Date | First Named Inventor, “Title” |
| 10/772,943 - Feb. 4, 2004 | Arat, et al., “Electrochemically Fabricated Microprobes” |
| 2005-0104609 - May 19, 2005 | |
| — | |
| 10/949,738 - Sep. 24, 2004 | Kruglick, et al., “Electrochemically Fabricated |
| 2006-0006888 - Jan. 12, 2006 | Microprobes” |
| — | |
| 11/028,945 - Jan. 3, 2005 | Cohen, et al., “A Fabrication Process for Co-Fabricating a |
| 2005-0223543 - Oct. 13, 2005 | Multilayer Probe Array and a Space Transformer |
| 7,640,651 - Jan. 5, 2010 | |
| 11/028,960 - Jan. 3, 2005 | Chen, et al. “Cantilever Microprobes for Contacting |
| 2005-0179458 - Aug. 18, 2005 | Electronic Components and Methods for Making Such |
| U.S. Pat. No. 7,265,565 - | Probes |
| Sep. 4, 2007 | |
| 11/029,180 - Jan. 3, 2005 | Chen, et al. “Pin-Type Probes for Contacting Electronic |
| 2005-0184748 - Aug. 25, 2005 | Circuits and Methods for Making Such Probes” |
| — | |
| 11/029,217 - Jan. 3, 2005 | Kim, et al., “Microprobe Tips and Methods for Making” |
| 2005-0221644 - Oct. 6, 2005 | |
| 7,412,767 - Aug. 19, 2008 | |
| 11/173,241 - Jun. 30, 2005 | Kumar, et al., Probe Arrays and Method for Making |
| 2006-0108678 - May 25, 2006 | |
| — | |
| 11/178,145 - Jul. 7, 2005 | Kim, et al., “Microprobe Tips and Methods for Making” |
| 2006-0112550 - Jun. 1, 2006 | |
| 7,273,812 - Sep. 25, 2007 | |
| 11/325,404 - Jan. 3, 2006 | Chen, et al., “Electrochemically Fabricated Microprobes” |
| 2006-0238209 - Oct. 26, 2006 | |
| — | |
| 14/986,500 - Dec. 31, 2015 | Wu, et al. “Multi-Layer, Multi-Material Micro-Scale and |
| 2016-0231356 - Aug. 11, 2016 | Millimeter-Scale Devices with Enhanced Electrical and/or |
| — | Mechanical Properties” |
| 16/172,354 - Oct. 18, 2018 | Chen, et al. “Pin-Type Probes for Contacting Electronic |
| 2019-0204354 - Jul. 4, 2019 | Circuits and Methods for Making Such Probes” |
| — | |
| 16/584,818 - Sep. 26, 2019 | Smalley, “Probes Having Improved Mechanical and/or |
| — | Electrical Properties for Making Contact between |
| — | Electronic Circuit Elements and Methods for Making” |
| 16/584,863 - Sep. 26, 2019 | Frodis, “Probes Having Improved Mechanical and/or |
| — | Electrical Properties for Making Contact between |
| — | Electronic Circuit Elements and Methods for Making” |
| 62/961,672 - Jan. 15, 2020 | Wu, “Compliant Pin Probes with Multiple Spring Segments |
| (P-US381-B-MF) | and Compression Spring Deflection Stabilization |
| | Structures, Methods for Making, and Methods for Using” |
| 62/961,675 - Jan. 15, 2020 | Wu, “Probes with Multiple Springs, Methods for Making, |
| (P-US382-B-MF) | and Methods for Using” |
| 62/961,678 - Jan. 15, 2020 | Wu, “Compliant Pin Probes with Flat Extension Springs, |
| (P-US383-B-MF) | Methods for Making, and Methods for Using” |
| 16/791,288 - Feb. 14, 2020 | Frodis, “Multi-Beam Vertical Probes with Independent |
| (P-US385-A-MF) | Arms Formed of a High Conductivity Metal for Enhancing |
| NP OF P-US370-A-MF | Current Carrying Capacity and Methods for Making Such |
| | Probes” |
| 63/015,450 - Apr. 24, 2020 | Lockard, “Buckling Beam Probe Arrays and Methods for |
| (P-US390-A-MF) | Making Such Arrays Including Forming Probes with |
| | Lateral Positions Matching Guide Plate Hole Positions and |
| | Integrating Guides” |
| 17/139,933 - Dec. 31, 2020 | Wu, “Compliant Pin Probes with Multiple Spring Segments |
| (P-US399-A-MF) | and Compression Spring Deflection Stabilization |
| NP OF P-US381-B-MF | Structures, Methods for Making, and Methods for Using” |
| 17/139,936 - Dec. 31, 2020 | Wu, “Probes with Multiple Springs, Methods for Making, |
| (P-US400-A-MF) | and Methods for Using” |
| NP OF P-US382-B-MF | |
| 17/139,940 - Dec. 31, 2020 | Wu, “Compliant Pin Probes with Flat Extension Springs, |
| (P-US401-A-MF) | Methods for Making, and Methods for Using” |
| NP OF P-US383-B-MF | |
| 17/240,962 - Apr. 26, 2021 | Lockard, “Buckling Beam Probe Arrays and Methods for |
| (P-US405-A-MF) | Making Such Arrays Including Forming Probes with |
| NP OF P-US390-A-MF | Lateral Positions Matching Guide Plate Hole Positions” |
| 63/217,721 - Jul. 1, 2021 | Wu, “Compliant Pin Probes with Extension Springs, |
| (P-US402-B-MF) | Methods for Making, and Methods for Using” |
| 17/320,173 - May 13, 2021 | Lockard, “Vertical Probe Arrays and Improved Methods for |
| (P-US406-A-MF) | Making Using Temporary or Permanent Alignment |
| NP OF P-US387-A-MF | Structures for Setting or Maintaining Probe-to-Probe |
| | Relationships” |
| 17/384,680 - Jul. 23, 2021 | Yaglioglu, “Methods for Making Probe Arrays Utilizing |
| (P-US407-A-MF) | Lateral Plastic Deformation of Probe Preforms” |
| NP OF P-US392-A-MF | |

### Electrochemical Fabrication:

Electrochemical fabrication techniques for forming three-dimensional structures from a plurality of adhered layers have been, and are being, commercially pursued by Microfabrica® Inc. (formerly MEMGen Corporation) of Van Nuys, California under the process names EFAB and MICA FREEFORM®.

Various electrochemical fabrication techniques were described in U.S. Pat. No. 6,027,630, issued on Feb. 22, 2000 to Adam Cohen.

A related method for forming microstructures using electrochemical fabrication techniques is taught in U.S. Pat. No. 5,190,637 to Henry Guckel, entitled “Formation of Microstructures by Multiple Level Deep X-ray Lithography with Sacrificial Metal Layers”.

FIGS. 1A-11 illustrate side views of various states in an example multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metals form part of the layer. In FIG. 1A, a side view of a substrate 182 having a surface 188 is shown, onto which patternable photoresist 184 is deposited, spread, or cast as shown in FIG. 1B. In FIG. 1C, a pattern of resist is shown that results from the curing, exposing, and developing of the resist. The patterning of the photoresist 184 results in openings or apertures 192(a) -192(c) extending from a surface 186 of the photoresist through the thickness of the photoresist to surface 188 of the substrate 182. In FIG. 1D, a metal 194 (e.g. nickel) is shown as having been electroplated into the openings 192(a) -192(c). In FIG. 1E, the photoresist has been removed (i.e. chemically stripped) from the substrate to expose regions of the substrate 182 which are not covered with the first metal 194. In FIG. 1F, a second metal 196 (e.g. silver) is shown as having been blanket electroplated over the entire exposed portions of the substrate 182 (which is conductive) and over the first metal 194 (which is also conductive). FIG. 1G depicts the completed first layer of the structure which has resulted from the planarization of the first and second metals down to a height that exposes the first metal and sets a thickness for the first layer. In FIG. 1H, the result of repeating the process steps shown in FIGS. 1B-1G several times to form a multi-layer structure is shown where each layer consists of two materials. For most applications, one of these materials is removed as shown in FIG. 1I to yield a desired 3-D structure 198 (e.g. component or device).

Electrochemical fabrication provides the ability to form prototypes and commercial quantities of miniature objects, parts, structures, devices, and the like at reasonable costs and in reasonable times. In fact, electrochemical fabrication is an enabler for the formation of many structures that were hitherto impossible to produce. Electrochemical fabrication opens the spectrum for new designs and products in many industrial fields. Even though electrochemical fabrication offers this new capability and it is understood that electrochemical fabrication techniques can be combined with designs and structures known within various fields to produce new structures, certain uses for electrochemical fabrication provide designs, structures, capabilities and/or features not known or obvious in view of the state of the art.

A need exists in various fields for miniature devices having improved characteristics, improved operational capabilities, reduced fabrication times, reduced fabrication costs, simplified fabrication processes, greater versatility in device design, improved selection of materials, improved material properties, more cost effective and less risky production of such devices, and/or more independence between geometric configuration and the selected fabrication process.

### SUMMARY OF THE INVENTION

It is an object of some embodiments of the invention to provide improved probes.

It is an object of some embodiment of the invention to provide improved probe arrays

It is an object of some embodiments to provided improved deformation tools and methods of engaging such tools with preform arrays and removing such tools from the preform arrays after deformation or using such tools as array frame elements (e.g., guide plates) after deformation.

It is an object of some embodiments of the invention to provide improved methods for making probes or groups of probes, e.g., including use of plastic deformation that provides for extended length of probe preforms or preform arrays.

It is an object of some embodiments of the invention to provide improved methods for making probe arrays with less assembly.

It is an object of some embodiments of the invention to decouple, at least in part, probe array formation time, cost, and/or effort from the number of probes that will form part of the array by reducing assembly cost, time, and effort.

It is an object of some embodiments of the invention to provide improved methods of using probe arrays.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not necessarily intended that multiple objects of the invention be addressed by any single aspect of the invention even though that may be the case with regard to some aspects.

In a first aspect of the invention, a method of forming a probe array is provided, including: (a) forming an array preform including: (i) providing a build substrate; (ii) forming at least portions of a plurality of probe preforms using a multi-layer, multi-material fabrication process with a first layer being formed directly or indirectly on the build substrate, wherein each of the preforms include at least one spring region; (b) engaging at least one deformation tool with the probe preforms of the array preform; and (c) transforming the probe preforms using the at least one deformation tool to longitudinally and plasticly deform the at least one spring region of the preforms to extend the length of the preforms while in an array configuration.

Numerous variations of the first aspect of the invention are possible and include, for example: (1) the method additionally including a lateral plastic deformation of the spring regions of the preforms as well as the longitudinal deformation; (2) variation 1 wherein at least a portion of the lateral and longitudinal deformations occur in a manner selected from the group consisting of: (i) as simultaneous deformations, (ii) as series deformations, (iii) in a plurality of alternating longitudinal and lateral deformations, (iv) setting deformation movement after compensating for elastic spring back before at least some deformations to better match actual deformation to a targeted deformation level or position, and (v) measuring an actual amount of plastic deformation or position and comparing it to a targeted amount and performing additional deformation if the measured amount is not within a defined tolerance of the targeted amount; (3) the preforms being assigned to groups and deformation occurs in a series of movements on a group-by-group basis; (4) variation 3 wherein the basis is selected from the group consisting of: (i) deformation of one group after deformation of another; (ii) deformation of one group and deformation of another group where only a portion of the deformation occur simultaneously, (iii) deformation of groups simultaneously but using different amounts of motion; (iv) multi-step deformation of one group along with single step deformation of another, (v) multi-step deformation of one group along with single step deformation of another wherein the none of the deformation occurs simultaneously, (vi) multi-step deformation of one group along with single step deformation of another wherein single step deformation occurs simultaneous with one of the multi-step deformations; (vii) multi-step deformation of one group along with multi-step deformation of another group wherein none of the deformations occur simultaneously, (viii) multi-step deformation of one group along with multi-step deformation of another group wherein a portion of the deformation occur simultaneously; (ix) multi-step deformation of one group along with multi-step deformation of another group wherein at least some of the deformations have different amounts of motions; and (x) wherein a different amount of spring back is compensated for in deformation one group versus another group; (5) the spring region of each of a plurality of probe preforms including at least one spring element selected from the group consisting of: (i) a single laterally configured planar spring element, (ii) a plurality of laterally configured planar spring elements connected by longitudinally oriented bridge elements, (iii) at least one multi-step region comprising a plurality of laterally offset elements stacked directly or indirectly on other laterally offset elements, (iv) at least one multi-step region comprising a plurality of laterally offset elements stacked directly or indirectly on other laterally offset elements wherein the laterally offset elements are elongated elements; (6) at least some preforms having portions that laterally overlay or underlay portions of adjacent probes wherein the overlaying or underlaying portions are longitudinally offset from each other; (7) variation 6 wherein upon deformation, the overlaying or underlaying lateral portions of adjacent probes do not contact one another; (8) variation 6 wherein upon deformation, the overlaying or underlaying lateral portions contact but slide past one another such that, when in a final extended state and in an operation state, adjacent probes do not come into direct physical contact; (9) the build structure functioning as an array substrate when the array is in use; (10) the build substrate being removed from the probe array or preform array prior to putting the probe array to use; (11) variation 10 wherein an array substrate is attached to the probe preforms or probes at a time selected from the group consisting of: (i) prior to putting the probe array into use, (ii) prior to transforming the probe preforms, (iii) after at least partially transforming the probe preforms, and (iv) after completely transforming the probe preforms; (12) the method of forming the probe array additionally including engaging at least one guide plate with the probe preforms or probes; (13) the multi-layer, multi-material fabrication process including forming a plurality of multi-material layers representing at least portions of cross-sections of the plurality of probe preforms, wherein each successive layer formed is formed on and adhered to an immediately preceding layer wherein each of at least a portion of the plurality of layers includes at least two materials with at least one being a structural material and with at least one being a sacrificial material, wherein the formation of each such multi-material layer includes: (A) depositing a first of the at least two materials; (B) depositing a second of the at least two materials, (C) planarizing a plurality of the at least two materials; (14) the preforms including one or more planar elements (e.g. spiral, straight, bent, or meandering structures) that undergo longitudinal extension to obtain a probe height that is greater than a preform height when not under an external load; (15) variation 14 wherein the preforms also undergo longitudinal and/or lateral extension to provide the probes with desired X and Y end locations when not under an external load; (16) first ends of the probe preforms being bonded to the build substrate and wherein the deformation occurs by bonding a second region of each preform that is separated from the first end by at least one elongated structure having at least one laterally extended section (e.g. the second region may be at or near and end of the probe, e.g. within 1, 3, or 5 layers from the second end or within 5%, 10%, or even 20% the full length of the probe after deformation, and the bonding may be by solder or a solidified polymer), either before or after release of the preforms from a sacrificial material, to at least one deformation tool, then longitudinally separating the substrate and the at least one deformation tool to cause plastic deformation, and thereafter releasing the second regions from the deformation structure; (17) each probe further including a probe tip including a material that is different from a material of a spring region; (18) variation 17 wherein the probe tip forms part of the probe preform prior to any deformation; (19) variation 17 wherein the probe tips are added after at least partial plastic deformation of the probe preforms; (20) each probe further including a probe tip wherein a spring region includes a material different from a probe tip material; (21) variation 20 wherein the probe tip forms part of the probe preform prior to any deformation; (22) variation 20 wherein the probe tips are added after at least partial plastic deformation of the probe preforms; (23) additionally including at least one process step that modifies at least one intrinsic material property of at least a portion of the spring region of the probe prior to that portion of the probe undergoing deformation wherein the one or more process steps are selected from the group consisting of: (i) heat treating to cause annealing of the at least a portion of the spring region, (ii) heat treating to cause hardening of the at least portion of the spring region, and (iii) heat treating in the presence of one or more of an applied material, a non-atmospheric gaseous material, a liquid material, a vacuum, a magnetic field, an electric field to tailor material properties (e.g. to provide tailored spring constant, tailored plastic or elastically deformation properties, tailored magnetic properties, tailored surface properties (e.g. hardness), tailored electrical properties, improved interlayer adhesion, provision of conductive or dielectric surface properties); (24) additionally including at least one process step that modifies at least one intrinsic material property of at least a portion of the spring region of the probe after that portion of the probe undergoes deformation but before removal of the deformation tool wherein the one or more process steps are selected from the group consisting of: (i) heat treating to cause annealing of the at least a portion of the spring region, (ii) heat treating to cause hardening of the at least a portion of the spring region, and (iii) heat treating in the presence of one or more of an applied material, a non-atmospheric gaseous material, a liquid material, a vacuum, a magnetic field, an electric field to tailor material properties (e.g. to provide tailored spring constant, tailored plastic or elastically deformation properties, tailored magnetic properties, tailored surface properties (e.g. hardness), tailored electrical properties, improved interlayer adhesion, provision of conductive or dielectric surface properties); (25) additionally including at least one process step that modifies at least one intrinsic material property of at least a portion of the spring region of the probe after that portion of the probe undergoes deformation and after removal of the deformation tool wherein the one or more process steps are selected from the group consisting of: (i) heat treating to cause annealing of the at least a portion of the spring region, (ii) heat treating to cause hardening of the at least a portion of the spring region, and (iii) heat treating in the presence of one or more of an applied material, a non-atmospheric gaseous material, a liquid material, a vacuum, a magnetic field, an electric field to tailor material properties (e.g. to provide tailored spring constant, tailored plastic or elastically deformation properties, tailored magnetic properties, tailored surface properties (e.g. hardness), tailored electrical properties, improved interlayer adhesion, provision of conductive or dielectric surface properties); (26) the method including addition of a sacrificial material, post release sacrificial material or structure to aid in deforming the spring portion wherein the sacrificial material or structure can be removed via dissolving after deformation; (27) additionally including temporary encasement of probes after deformation to allow planarization of probe ends to common heights; (28) additionally including permanent encasement of at least portions of the probes by a dielectric material to add in providing one or both of durability and enhanced spring force; (29) a plurality of probes having probe bodies including a configuration selected from the group consisting of: (i) a single strand of deformable material, (ii) multiple parallel strands of deformable material, and (iii) multiple serial strands of deformable material formed on at least two different layers with deposited material of the serial strands formed in XY positions that are common between their respective layers but are not directly touching due to the presence of a gap in structural material on at least one separating layer; and (30) features and variations associated with the different embodiments set forth herein directly as well as features and variations of the embodiments or aspects set forth in some of the patents and applications incorporated herein by reference.

In a second aspect of the invention, a probe array is provided, including: (a) a plurality of probes; and (b) at least one probe retention structure for holding the probes in an array configuration, wherein individual probes have stair-stepped surface configurations with stair-steps having at least two different orientations on at least two different portions of individual probes.

Numerous variations of the second aspect of the invention are possible and include, for example: (1) the variations noted above, mutatis mutandis, for the first aspect, (2) features and variations associated with the different embodiments set forth herein directly, (3) features and variations of the embodiments or aspects set forth in some of the patents and applications incorporated herein by reference, (4) the at least two different orientations and portions being at least three different orientations and three different portions.

Other aspects of the invention will be understood by those of skill in the art upon review of the teachings herein. Other aspects of the invention may involve combinations of the above noted aspects of the invention and variations of the first and second aspects. These other aspects of the invention may provide other configurations, structures, functional relationships, and processes.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 11 respectively depict the state of the process after formation of the multiple layers of the structure and after release of the structure from the sacrificial material.

FIG. 2 provides a flow chart according to some embodiments of the invention where probe preforms are formed in a lateral array pattern (e.g. in X & Y) and then at least longitudinally plastically deformed to extend compliant/elastic portions of the probe preforms in length (e.g. in Z).

FIG. 3 provides a flow chart according to some other embodiments of the invention where probe preforms may not be formed in an array formation but instead be either placed in an array formation and then longitudinally plastically deformed or plastically deformed and then placed in an array formation as indicated in the two alternatives shown in the flowchart of FIG. 3.

FIGS. 4A-4N illustrate an example probe array and various states in a process of forming the example probe array according to a specific embodiment of the invention using a combination of side views, cut side views, top views, and top cut views where the array has a plurality of probes having single spring elements that are laterally planar and have spiral configurations (prior to deformation) which are longitudinally deformed while in an array configuration to enhance probe height.

FIGS. 5A1-5H illustrate an example probe array and various states in a process of forming the example probe array according to another specific embodiment of the invention using a combination of cut side views and a top view where the array has a plurality of probes having three stages of angled stair-stepped spring elements located in series to form S-like inverted interlaced probes that start off as longitudinally compact preforms (prior to deformation) which are longitudinally deformed while in an array configuration to enhance probe length and spacing between the probe bodies.

FIGS. 6A1-6C6 illustrate an example probe array and various states in a process of forming the probe array according to another specific embodiment of the invention using a combination of a cut side view of an array preform and deformation tools, as formed or positioned, but without showing sacrificial material (FIG. 6A1), a table providing a legend or key to hatching patterns used in the illustrations (FIG. 6A2), top views of successively formed layers of the preform array and deformation tools, including a substrate outline for maintaining lateral registration perspective from layer-to-layer (FIGS. 6B1-6B14), side views of the probe preform array as it transitions through various levels of deformation from an undeformed array to a fully deformed array wherein deformation occurs on a probe group-by-probe group basis to minimize risk of collisions of partially overlapping preforms (FIGS. 6C1-6C5), and side view of a final array after deformation and removal of deformation tools (FIG. 6C6).

FIG. 7A-7K2 provide block diagrams of example process elements and/or variables that may be used in alternative embodiments of the invention along with some sample values or variations that the element or variable might take.

### DETAILED DESCRIPTION OF PREFERRED EMBODIMENTS

Electrochemical Fabrication in General

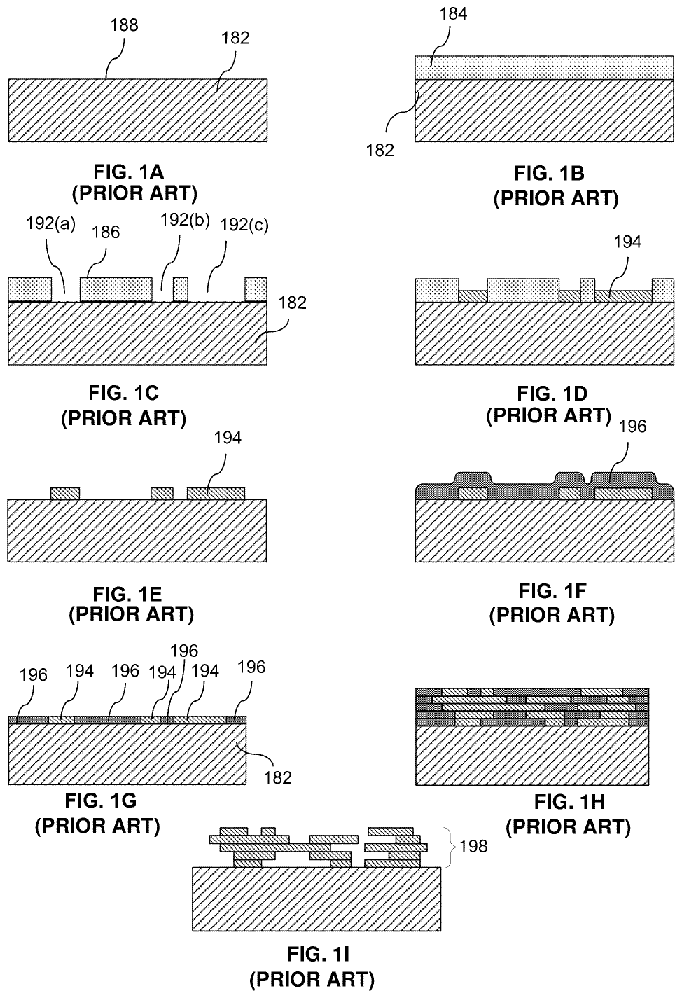

An example of a multi-layer, multi-material electrochemical fabrication process was provided above in conjunction with the illustrations of FIGS. 1A-11. In some variations, the structure may be separated from the substrate. For example, release of the structure (or multiple structures if formed in a batch process) from the substrate may occur when releasing the structure from the sacrificial material particularly when a layer of sacrificial material is positioned between the first layer of the structure and the substrate. Alternative methods may involve, for example, the use of a dissolvable substrate that may be separated before, during or after removal of the sacrificial material, machining off the substrate before or after removal of the sacrificial material, or use of a different intermediate material that can be dissolved, melted or otherwise used to separate the structure(s) from the substrate before, during, or after removal of the sacrificial material that surround the structure(s).

Various embodiments of various aspects of the invention are directed to formation of three-dimensional structures from materials, some, or all, of which may be electrodeposited or electroless deposited (as illustrated in FIGS. 1A-11 and as discussed in various patents and patent applications incorporated herein by reference). Some of these structures may be formed from a single build level (e.g. a planarized layer) that is formed from one or more deposited materials while others are formed from a plurality of build levels, each generally including at least two materials (e.g. two or more layers, five or more layers, and even ten or more layers). In some embodiments, layer thicknesses may be as small as one micron or as large as one hundred to two hundred microns. In still other embodiments, layers may be up to five hundred microns, one millimeter, even multiple millimeters, or more. In other embodiments, thinner layers may be used. In still other embodiments, layer thickness may be varied during formation of different levels of the same structure. In some embodiments, microscale structures have lateral features positioned with 0.1-10 micron level precision and minimum feature sizes on the order of microns to tens of microns. In other embodiments, structures with less precise feature placement and/or larger minimum features may be formed. In still other embodiments, higher precision and smaller minimum feature sizes may be desirable. In the present application, meso-scale and millimeter-scale have the same meaning and refer to devices that may have one or more dimensions that may extend into the 0.1-50 millimeter range, or somewhat larger, and features positioned with a precision in the micron to 100 micron range and with minimum feature sizes on the order of several microns to hundreds of microns.

The various embodiments, alternatives, and techniques disclosed herein may form multi-layer structures using a single patterning technique on all layers or using different patterning techniques on different layers. For example, various embodiments of the invention may perform selective patterning operations using conformable contact masks and masking operations (i.e. operations that use masks which are contacted to but not adhered to a substrate), proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), adhered masks and masking operations (masks and operations that use masks that are adhered to a substrate onto which selective deposition or etching is to occur as opposed to only being contacted to it), and/or selective patterned deposition of materials (e.g. via extrusion, jetting, or controlled electrodeposition) as opposed to masked patterned deposition. Conformable contact masks, proximity masks, and non-conformable contact masks share the property that they are preformed and brought to, or in proximity to, a surface which is to be treated (i.e. the exposed portions of the surface are to be treated). These masks can generally be removed without damaging the mask or the surface that received treatment to which they were contacted or located in proximity to. Adhered masks are generally formed on the surface to be treated (i.e. the portion of that surface that is to be masked) and bonded to that surface such that they cannot be separated from that surface without being completely destroyed or damaged beyond any point of reuse. Adhered masks may be formed in a number of ways, including: (1) by application of a photoresist, selective exposure of the photoresist, and then development of the photoresist, (2) selective transfer of pre-patterned masking material, (3) direct formation of masks from computer-controlled depositions of material, and/or (4) laser ablation of a deposited material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels (i.e. regions that lie within the top and bottom boundary levels that define a different layer's geometric configuration). Such use of selective etching and/or interlaced material deposition in association with multiple layers is described in U.S. patent application Ser. No. 10/434,519, by Smalley, filed May 7, 2003, which is now U.S. Pat. No. 7,252,861, and which is entitled “Methods of and Apparatus for Electrochemically Fabricating Structures Via Interlaced Layers or Via Selective Etching and Filling of Voids”. This referenced application is incorporated herein by reference.

Temporary substrates on which structures may be formed may be of the sacrificial-type (i.e. destroyed or damaged during separation of deposited materials to the extent they cannot be reused), non-sacrificial-type (i.e. not destroyed or excessively damaged, i.e. not damaged to the extent they may not be reused, e.g. with a sacrificial or release layer located between the substrate and the initial layers of a structure that is formed). Non-sacrificial substrates may be considered reusable, with little or no rework (e.g. planarizing one or more selected surfaces or applying a release layer, and the like) though they may or may not be reused for a variety of reasons.

Definitions of various terms and concepts that may be used in understanding the embodiments of the invention (either for the devices themselves, certain methods for making the devices, or certain methods for using the devices) will be understood by those of skill in the art. Some such terms and concepts are discussed herein while other such terms are addressed in the various patent applications to which the present application claims priority and/or which are incorporated herein by reference.

### Definitions

This section of the specification is intended to set forth definitions for a number of specific terms that may be useful in describing the subject matter of the various embodiments of the invention. It is believed that the meanings of most if not all these terms are clear from their general use in the specification, but they are set forth hereinafter to remove any ambiguity that may exist. It is intended that these definitions be used in understanding the scope and limits of any claims that use these specific terms. As far as interpretation of the claims of this patent disclosure are concerned, it is intended that these definitions take precedence over any contradictory definitions or allusions found in any materials which are incorporated herein by reference. Additional definitions and information about electrochemical fabrication methods may be found in a number of the various applications incorporated herein by reference just as for example, U.S. patent application Ser. No. 16/584,818, filed Sep. 26, 2019 and entitled “Probes Having Improved Mechanical and/or Electrical Properties for Making Contact Between Electronic Circuit Elements and Methods for Making”.

“Probe preform” refers to a probe, or probe portion that includes at least a portion of a compliant section of the probe, that has not yet undergone longitudinal extension as a result of subjecting at least part of a compliant section of the probe to a force that caused longitudinal plastic deformation of at least a portion of a compliant section of the probe so as to cause longitudinal extension of that portion of the probe. Depending on the context of usage, a probe preform may include all structural components and features of a completed probe (other than not yet having undergone stretching).

“Array preform” refers to a plurality of probe preforms that exist in an array configuration which have not yet undergone longitudinal plastic deformation that causes at least some longitudinal extension.

“Longitudinal” as used herein refers to a long dimension of a probe, an end-to-end dimension of the probe, or a tip-to-tip dimension. Longitudinal may refer to a generally straight line that extends from one end of the probe to another end of the probe or it may refer to a curved or stair-stepped path that has a sloped or even changing direction along a height of the probe. When referring to probe arrays, the longitudinal dimension may refer to a particular direction the probes in the array point or extend, but it may also simply refer to the overall height of the array that starts at a plane containing a first end, tip, or base of a plurality of probes and extends perpendicular thereto to a plane containing a second end, tip, or top of the probes. The context of use typically makes clear what is meant especially to those of skill in the art. It is intended that the interpretation to be applied to the term herein be as narrow as warranted by the details of the description provided or the context in which the term is used. If however, no such narrow interpretation is warranted, it is intended that the broadest reasonable scope of interpretation apply.

“Lateral” as used herein is related to the term longitudinal. In terms of the stacking of layers, lateral refers to a direction within each layer, or two perpendicular directions within each layer (i.e. one or more directions that lie within a plane of a layer that is substantially perpendicular to the longitudinal direction). When referring to probe arrays, lateral generally has a similar meaning in that a lateral dimension is generally a dimension that lies in a plane that is parallel to a plane of the top or bottom of the array (i.e. substantially perpendicular to the longitudinal dimension). When referring to probes themselves, the lateral dimensions may be those that are perpendicular to an overall longitudinal axis of the probe, a local longitudinal axis of the probe (that is, local lateral dimensions), or simply the dimensions similar to those noted for arrays or layers. The context of use typically makes clear what is meant especially to those of skill in the art. It is intended that the interpretation to be applied to the term herein be as narrow as warranted by the details of the description provided or the context in which the term is used. If no such narrow interpretation is warranted, it is intended that the broadest reasonable scope of interpretation apply.

“Build” as used herein refers, as a verb, to the process of building a desired structure (or part) or plurality of structures (or parts) from a plurality of applied or deposited materials which are stacked and adhered upon application or deposition or, as a noun, to the physical structure (or part) or structures (or parts) formed from such a process. Depending on the context in which the term is used, such physical structures may include a desired structure embedded within a sacrificial material or may include only desired physical structures which may be separated from one another or may require dicing and/or slicing to cause separation.

“Build axis” or “build orientation” is the axis or orientation that is substantially perpendicular to substantially planar levels of deposited or applied materials that are used in building up a structure. The planar levels of deposited or applied materials may be or may not be completely planar but are substantially so in that the overall extent of their cross-sectional dimensions are significantly greater than the height of any individual deposit or application of material (e.g. 100, 500, 1000, 5000, or more times greater). The planar nature of the deposited or applied materials may come about from use of a process that leads to planar deposits or it may result from a planarization process (e.g. a process that includes mechanical abrasion, e.g. lapping, fly cutting, grinding, or the like) that is used to remove material regions of excess height. Unless explicitly noted otherwise, “vertical” as used herein, when referring to fabrication, refers to the build axis or nominal build axis (if the layers are not stacking with perfect registration) while “horizontal” refers to a direction within the plane of the layers (i.e. the plane that is substantially perpendicular to the build axis). As used with respect to probes, vertical generally refers to a probe configuration that is generally longitudinally extended and laterally much smaller in dimension (e.g. resulting in a ratio of 50 to one or more) or refers to probe arrays where an end-to-end orientation of the probes are set within about 45 degrees of the longitudinal axis of the probe array.

“Build layer” or “layer of structure” as used herein does not refer to a deposit of a specific material but instead refers to a region of a build located between a lower boundary level and an upper boundary level which generally defines a single cross-section of a structure being formed or structures which are being formed in parallel. Depending on the details of the actual process used to form the structure, build layers are generally formed on and adhered to previously formed build layers. In some processes, the boundaries between build layers are defined by planarization operations which result in successive build layers being formed on substantially planar upper surfaces of previously formed build layers. In some embodiments, the substantially planar upper surface of the preceding build layer may be textured to improve adhesion between the layers. In other build processes, openings may exist in or be formed in the upper surface of a previous but only partially formed build layers such that the openings in the previous build layers are filled with materials deposited in association with current build layers which will cause interlacing of build layers and material deposits. Such interlacing is described in U.S. patent application Ser. No. 10/434,519, now U.S. Pat. No. 7,252,861. This referenced application is incorporated herein by reference as if set forth in full. In most embodiments, a build layer includes at least one primary structural material and at least one primary sacrificial material. However, in some embodiments, two or more primary structural materials may be used without a primary sacrificial material (e.g. when one primary structural material is a dielectric and the other is a conductive material) while in others, a build layer may contain only one or more sacrificial materials especially when such layers are directly or indirectly adhered to previously formed multi-material layers that contain structural materials and receive, directly or indirectly, one or more layers that contain structural materials. In some embodiments, build layers are distinguishable from each other by the source of the data that is used to yield patterns of the deposits, applications, and/or etchings of material that form the respective build layers. For example, data descriptive of a structure to be formed which is derived from data extracted from different vertical levels of a data representation of the structure define different build layers of the structure. The vertical separation of successive pairs of such descriptive data may define the thickness of build layers associated with the data. As used herein, at times, “build layer” may be loosely referred to simply as “layer”. In many embodiments, deposition thickness of primary structural or sacrificial materials (i.e., the thickness of any particular material after it is deposited) is generally greater than the layer thickness and a net deposit thickness is set via one or more planarization processes which may include, for example, mechanical abrasion (e.g., lapping, fly cutting, polishing, and the like) and/or chemical etching (e.g., using selective or non-selective etchants). The lower boundary and upper boundary for a build layer may be set and defined in different ways. From a design point of view, they may be set based on a desired vertical resolution of the structure (which may vary with height). From a data manipulation point of view, the vertical layer boundaries may be defined as the vertical levels at which data descriptive of the structure is processed or the layer thickness may be defined as the height separating successive levels of cross-sectional data that dictate how the structure will be formed. From a fabrication point of view, depending on the exact fabrication process used, the upper and lower-layer boundaries may be defined in a variety of different ways. For example, upper and lower-layer boundaries may be defined by planarization levels or effective planarization levels (e.g., lapping levels, fly cutting levels, chemical mechanical polishing levels, mechanical polishing levels, vertical positions of structural and/or sacrificial materials after relatively uniform etch back following a mechanical or chemical mechanical planarization process). For example, upper and lower-layer boundaries may be defined by levels at which process steps or operations are repeated. For example, upper and lower-layer boundaries may be defined at levels at which, at least theoretically, lateral extends of structural material can be changed to define new cross-sectional features of a structure.

“Layer thickness” is the height along the build axis between a lower boundary of a build layer and an upper boundary of that build layer.

“Planarization” is a process that tends to remove materials, above a desired plane, in a substantially non-selective manner such that all deposited materials are brought to a substantially common height or desired level (e.g. within 20%, 10%, 5%, or even 1% of a desired layer boundary level). For example, lapping removes material in a substantially non-selective manner, though some amount of recession of one material or another may occur (e.g. copper may recess relative to nickel). Planarization may occur primarily via mechanical means, e.g. lapping, grinding, fly cutting, milling, sanding, abrasive polishing, frictionally induced melting, other machining operations, or the like (i.e. mechanical planarization). Mechanical planarization may be followed or preceded by thermally induced planarization (e.g. melting) or chemically induced planarization (e.g. etching). Planarization may occur primarily via a chemical and/or electrical means (e.g. chemical etching, electrochemical etching, or the like). Planarization may occur via a simultaneous combination of mechanical and chemical etching (e.g. chemical mechanical polishing (CMP)).

“Structural material” as used herein refers to a material that remains part of the structure when put into use.

“Sacrificial material” is material that forms part of a build layer but is not a structural material. Sacrificial material on a given build layer is separated from structural material on that build layer after formation of that build layer is completed and more generally is removed from a plurality of layers after completion of the formation of the plurality of layers during a “release” process that removes the bulk of the sacrificial material or materials. In general, sacrificial material is located on a build layer during the formation of one, two, or more subsequent build layers and is thereafter removed in a manner that does not lead to a planarized surface. Materials that are applied primarily for masking purposes (i.e. to allow subsequent selective deposition or etching of a material, e.g. photoresist that is used in forming a build layer but does not form part of the build layer) or that exist as part of a build for less than one or two complete build layer formation cycles are not considered sacrificial materials as the term is used herein but instead shall be referred to as masking materials or as temporary materials. These separation processes are sometimes referred to as a release process and may or may not involve the separation of structural material from a build substrate. In many embodiments, sacrificial material within a given build layer is not removed until all build layers making up the three-dimensional structure have been formed. Sacrificial material may be, and typically is, removed from above the upper level of a current build layer during planarization operations during the formation of the current build layer. Sacrificial material is typically removed via a chemical etching operation but, in some embodiments, may be removed via a melting operation or electrochemical etching operation. In typical structures, the removal of the sacrificial material (i.e. release of the structural material from the sacrificial material) does not result in planarized surfaces but instead results in surfaces that are dictated by the boundaries of structural materials located on each build layer. Sacrificial materials are typically distinct from structural materials by having different properties therefrom (e.g. chemical etchability, hardness, melting point, etc.), but in some cases, as noted previously, what would have been a sacrificial material may become a structural material by its actual or effective encapsulation by other structural materials. Similarly, structural materials may be used to form sacrificial structures that are separated from a desired structure during a release process via the sacrificial structures being only attached to sacrificial material or potentially by dissolution of the sacrificial structures themselves using a process that is insufficient to reach structural material that is intended to form part of a desired structure. It should be understood that in some embodiments, small amounts of structural material may be removed, after or during release of sacrificial material. Such small amounts of structural material may have been inadvertently formed due to imperfections in the fabrication process or may result from the proper application of the process but may result in features that are less than optimal (e.g. layers with stair-steps in regions where smooth sloped surfaces are desired). In such cases, the volume of structural material removed is typically minuscule compared to the amount that is retained, and thus such removal is ignored when labeling materials as sacrificial or structural. Sacrificial materials are typically removed by a dissolution process, or the like, that destroys the geometric configuration of the sacrificial material as it existed on the build layers. In many embodiments, the sacrificial material is a conductive material such as a metal. As will be discussed hereafter, masking materials, though typically sacrificial in nature, are not termed sacrificial materials herein unless they meet the required definition of sacrificial material.

“Adhesion layer”, “seed layer”, “barrier layer”, and the like refer to coatings of material that are thin in comparison to the layer thickness and thus generally form secondary structural material portions or sacrificial material portions of some layers. Such coatings may be applied uniformly over a previously formed build layer, they may be applied over a portion of a previously formed build layer and over patterned structural or sacrificial material existing on a current (i.e. partially formed) build layer so that a non-planar seed layer results, or they may be selectively applied to only certain locations on a previously formed build layer. In the event such coatings are non-selectively applied, selected portions may be removed (1) prior to depositing either a sacrificial material or structural material as part of a current layer or (2) prior to beginning formation of the next layer or they may remain in place through the layer build up process and then etched away after formation of a plurality of build layers.

“Masking material” is a material that may be used as a tool in the process of forming a build layer but generally does not form part of that build layer. Masking material is typically a photopolymer or photoresist material or other material that may be readily patterned. Masking material is typically a dielectric. Masking material, though typically sacrificial in nature, is not generally a sacrificial material as used herein unless it forms part of a completed layer and generally has one or more subsequent layers formed thereon. Masking material is typically applied to a surface during the formation of a build layer for the purpose of allowing selective deposition, etching, or other treatment and is removed either during the process of forming that build layer or immediately after the formation of that build layer.

“Multilayer structures” are structures formed from multiple build layers of deposited or applied materials.

“Multilayer three-dimensional (or 3D or 3-D) structures” are multilayer structures where the structural material portion of at least one layer includes a region not bounded by the structural material of the other layer.

“Complex multilayer three-dimensional (or 3D or 3-D) structures” are multilayer three-dimensional structures formed from at least three layers where a line may be defined that hypothetically extends vertically through at least some portion of the build layers of the structure that will extend from structural material through sacrificial material and back through structural material or will extend from sacrificial material through structural material and back through sacrificial material (these might be termed vertically complex multilayer three-dimensional structures). Alternatively, complex multilayer three-dimensional structures may be defined as multilayer three-dimensional structures formed from at least two layers where a line may be defined that hypothetically extends horizontally through at least some portion of a build layer of the structure that will extend from structural material through sacrificial material and back through structural material or will extend from sacrificial material through structural material and back through sacrificial material (these might be termed horizontally complex multilayer three-dimensional structures). Worded another way, in complex multilayer three-dimensional structures, a vertically or horizontally extending hypothetical line will extend from one structural material or void (when the sacrificial material is removed) to the other of void or structural material and then back to structural material or void as the line is traversed along at least a portion of the line.

“Moderately complex multilayer three-dimensional (or 3D or 3-D) structures are complex multilayer 3D structures for which the alternating of void and structure or structure and void not only exists along one of a vertically or horizontally extending line but along lines extending both vertically and horizontally.

“Highly complex multilayer (or 3D or 3-D) structures are complex multilayer 3D structures for which the structure-to-void-to-structure or void-to-structure-to-void alternating occurs once along the line but occurs a plurality of times along a definable horizontally or vertically extending line.

“Minimum feature size” or “MFS” refers to a necessary or desirable spacing between structural material elements on a given layer that are to remain distinct in the final device configuration. If the minimum feature size is not maintained for structural material elements on a given layer, the fabrication process may result in structural material inadvertently bridging what were intended to be two distinct elements (e.g. due to masking material failure or failure to appropriately fill voids with sacrificial material during formation of the given layer such that, during formation of a subsequent layer, structural material inadvertently fills the void). More care during fabrication can lead to a reduction in minimum feature size. Alternatively, a willingness to accept greater losses in productivity (i.e. lower yields) can result in a decrease in the minimum feature size. However, during fabrication for a given set of process parameters, inspection diligence, and yield (successful level of production), a minimum design feature size is set in one way or another. The above described minimum feature size may more appropriately be termed minimum feature size of gaps or voids (e.g. the MFS for sacrificial material regions when sacrificial material is deposited first). Conversely a minimum feature size for structural material regions (minimum width or length of structural material elements) may be specified. Depending on the fabrication method and order of deposition of structural material and sacrificial material, the two types of minimum feature sizes may be the same or different. In practice, for example, using electrochemical fabrication methods as described herein, the minimum feature size on a given layer may be roughly set to a value that approximates the layer thickness used to form the layer, and it may be considered the same for both structural and sacrificial material widths. In some more rigorously implemented processes (e.g. with higher examination regiments and tolerance for rework), it may be set to an amount that is 80%, 50%, or even 30% of the layer thickness. Other values or methods of setting minimum feature sizes may be used. Worded another way, depending on the geometry of a structure, or plurality of structures, being formed, the structure, or structures, may include elements (e.g. solid regions) which have dimensions smaller than a first minimum feature size and/or have spacings, voids, openings, or gaps (e.g. hollow or empty regions) located between elements, where the spacings are smaller than a second minimum feature size where the first and second minimum feature sizes may be the same or different and where the minimum feature sizes represent lower limits at which formation of elements and/or spacing can be reliably formed. Reliable formation refers to the ability to accurately form or produce a given geometry of an element, or of the spacing between elements, using a given formation process, with a minimum acceptable yield. The minimum acceptable yield may depend on a number of factors including: (1) number of features present per layer, (2) numbers of layers, (3) the criticality of the successful formation of each feature, (4) the number and severity of other factors effecting overall yield, and (5) the desired or required overall yield for the structures or devices themselves. In some circumstances, the minimum size may be determined by a yield requirement per feature which is as low as 70%, 60%, or even 50%. While in other circumstances, the yield requirement per feature may be as high as 90%, 95%, 99%, or even higher. In some circumstances (e.g. in producing a filter element), the failure to produce a certain number of desired features (e.g. 20-40% failure) may be acceptable while in an electrostatic actuator, the failure to produce a single small space between two moveable electrodes may result in failure of the entire device. The MFS, for example, may be defined as the minimum width of a narrow and processing element (e.g. photoresist element or sacrificial material element) or structural element (e.g. structural material element) that may be reliably formed (e.g. 90-99.9 times out of 100) which is either independent of any wider structures or has a substantial independent length (e.g. 200-1000 microns) before connecting to a wider region.

Probes, Probe Arrays, and Methods of Making:

Various embodiments of probe preforms, probes, probe sub-arrays, array preforms, probe arrays, and methods of making them on space transformers, other electronic components, other active, or passive substrates, or for transferring and either attaching or contacting them to such substrates (e.g. probe card substrates) or for configuring and retaining such probes in array configurations using one or more guide plates or other retaining structures are set forth hereafter and/or in the materials incorporated herein by reference. Furthermore, implementation of various embodiments of the invention and numerous variations thereof may be aided, supplemented, or otherwise enhanced by inclusion of various teachings found in the materials incorporated herein by reference.

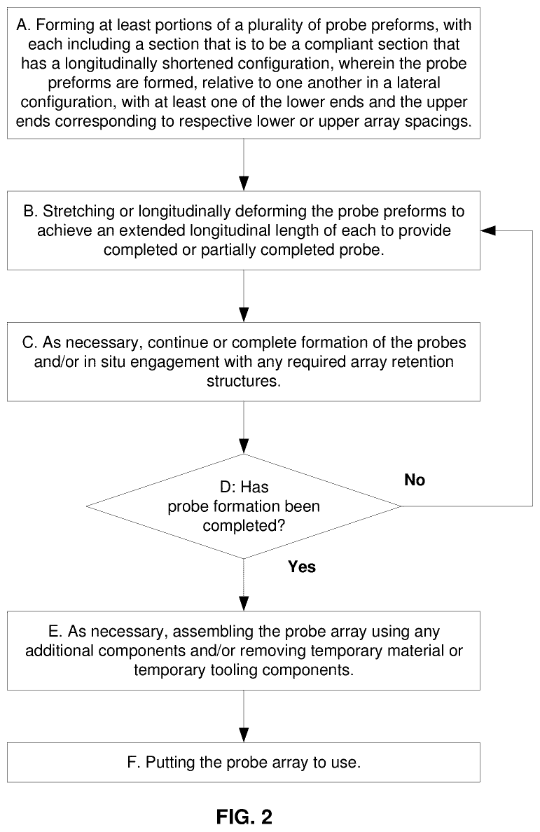

FIG. 2 provides a flow chart according to some embodiments of the invention where probe preforms are formed in a lateral array pattern (e.g. in X & Y) and then at least longitudinally extending the length or height (e.g. in Z) of preforms by plasticly deforming (e.g. bending or stretching) the preforms and more particularly by changing orientation of portions of the preforms that have laterally extended portions. Portions of probe preforms, for example, may be bent or reoriented from a more lateral configuration to a more longitudinal configurations.

The process of FIG. 2 begins with Block (A) which calls for forming at least portions of a plurality of probe preforms, with each including a section that is to be a compliant section (or spring section) that has a laterally extended and longitudinally shortened configuration, wherein the probe preforms are formed, relative to one another in a lateral configuration, with at least one of the lower ends and the upper ends of the preforms corresponding to respective lower or upper array spacings. In some variations the preforms may (1) represent entire longitudinally compressed probes, (2) represent probes or probe portions with additional material temporarily added, e.g., for tooling engagement or lateral preform-to-preform positioning maintenance, or (3) only probe portions which will be added to after deformation, or after initial deformation, to provide addition probe features, which may or may not undergo further deformation.

After Block (A), the process moves to Block (B) which calls for stretching or longitudinally deforming the probe preforms to achieve an extended longitudinal length of each to provide completed or partially completed probes. Before deformation, or even during preform formation, at least two separated regions of each the preform are engaged with deformation tooling which will eventually undergo separation. In some variations, all of the probe preforms undergo simultaneous deformation. In others, the probe preforms may be grouped such that preforms in different groups undergoing separate, or temporally staggered, deformation relative to preforms in other groups. Separation may occur by one or more longitudinal extension movements so that plastic deformation occurs. Such and extension or extensions may be accompanied, or separated by, lateral displacements between different vertical levels. The lateral displacement may contribute to plastic deformation, elastic biasing, or simply aid in temporary relative positioning for other purposes such as to avoid collisions between neighboring preform elements or even between different portions of individual preforms as they unfold or deform.

After Block (B), the process moves to optional Block (C) which calls for, as necessary, continuing and/or completing formation of the probes and/or in situ engagement with any required array retention structures (e.g., permanent substrates, guide plates, tiling structures, and the like).

After Block (C), the process moves to decision Block (D) which inquires has to whether probe formation has been completed (e.g., additional material must be added to the preforms, some temporary material must be removed from the preforms, and/or additional deformation is necessary). If not completed the process loops back to Step (B) but if completed from the process moves to Block (E).

After Block (D), the process moves to Block (E) which calls for, as necessary, assembling the probe array with any additional components and/or removing temporary materials of temporary tooling components. The assembly of the array may, for example, include (1) introducing an elastic biasing (or preloading) of the probes, (2) tiling of subarrays to form larger arrays, (3) replacing a temporary build substrate with a permanent substrate (e.g., a space transformer), (4) adding one or more guide plates, (5) longitudinally positioning guide plates, (6) treating the probes or probe portions to change material properties by heating, cooling, application of particular chemicals in solid, liquid or gaseous states, application of electric or magnetic fields, and the like. Some changes, for example might include hardening of the probe material, improve electrical conductivity, improve contact properties, providing dielectric insulation or conductive coatings, and the like.

After Block (E), the process ends with Block (F) which calls for putting the probe array to use. Use of the probe arrays might include testing applications such as wafer level semiconductor testing, burn-in testing, socket testing. In other situations use might include permanent mounting or contact applications.

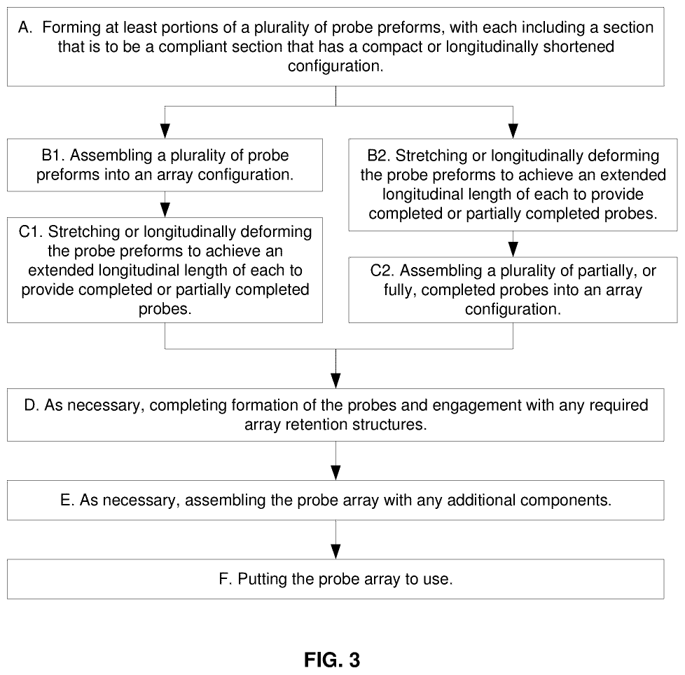

FIG. 3 provides a flow chart according to some other embodiments of the invention where probe preforms may not be formed in an array formation but instead be either placed in an array formation and then longitudinally plastically deformed or plastically deformed and then placed in an array formation as indicated in the two alternatives shown in the flowchart of FIG. 3.

The process of FIG. 3 begins with Block (A) which calls for forming at least portions of a plurality of probe preforms, with each including a section that is to be a compliant section (i.e., an elastically compliant section at least after probe formation and at the time of array usage) that has a compact or longitudinally shortened configuration. After Block (A), the process moves to either Block (B1), which calls for assembling a plurality of probe preforms into an array configuration, or Block (B2), which calls for stretching or longitudinally deforming the probe preforms to achieve an extended longitudinal length of each to provide completed or partially completed probes. If the process moved to Block (B1), after Block (B1), the process moves to Block (C1) which calls for stretching or longitudinally deforming the probe preforms to achieve an extended longitudinal length of each to provide completed or partially completed probes. If the process moved to Block (B2), after Block (B2), the process moves to Block (C2) which calls for assembling a plurality of partially, or fully, completed probes into an array configuration. After Block (C1) or Block (C2), the process moves to Block (D) which calls for, as necessary, completing formation of the probes and engagement with any required array retention structures. After Block (D), the process moves to Block (E) which calls for, as necessary, assembling the probe array with any additional components. After Block (E), the process ends with Block (F) which calls for putting the probe array to use.

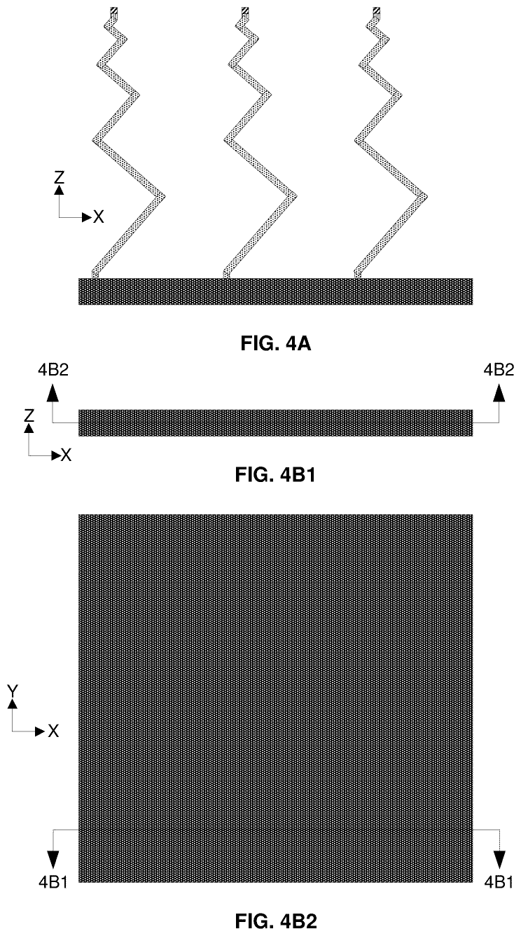

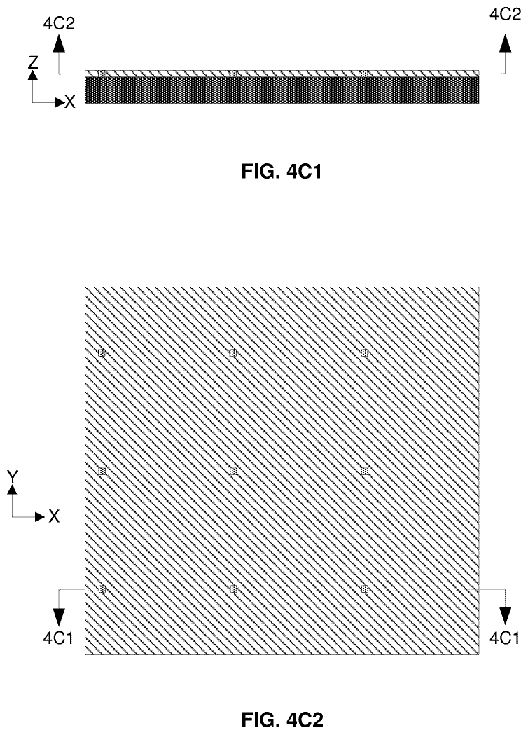

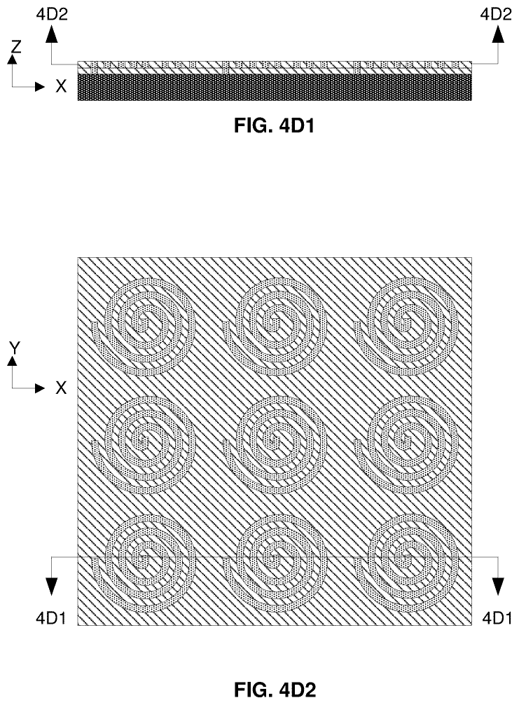

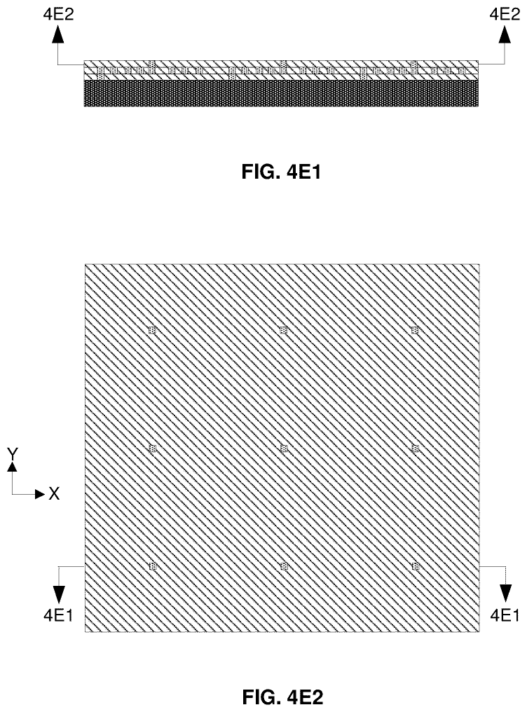

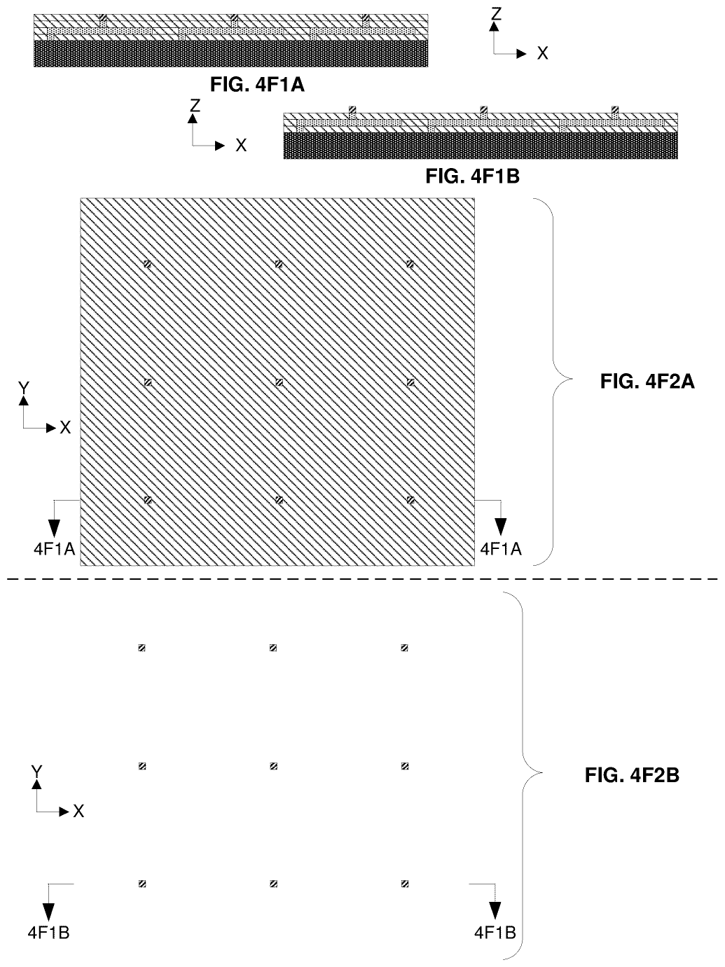

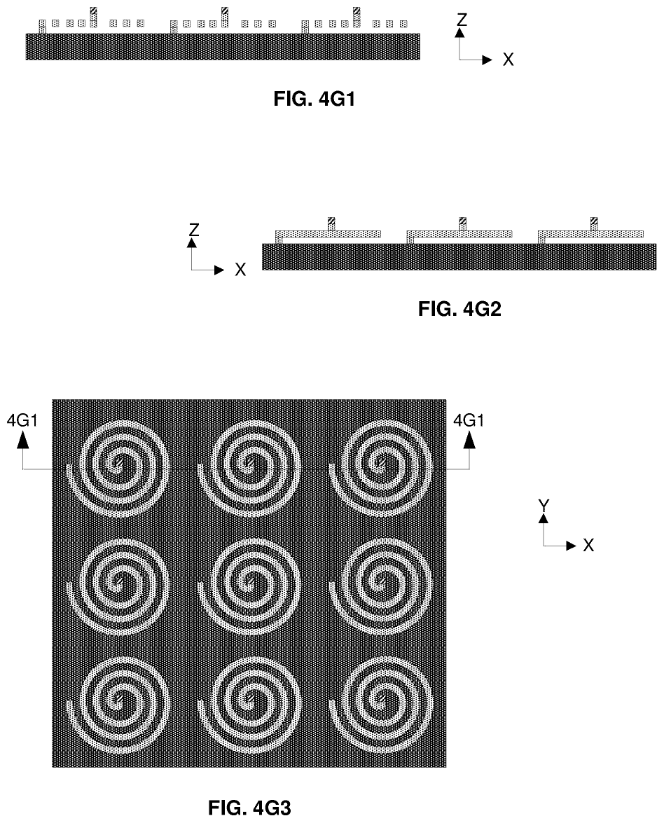

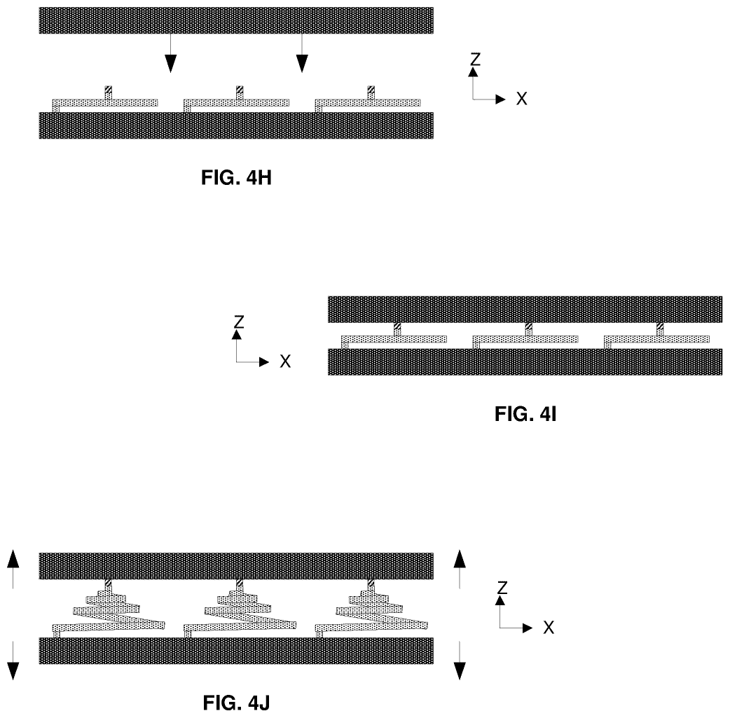

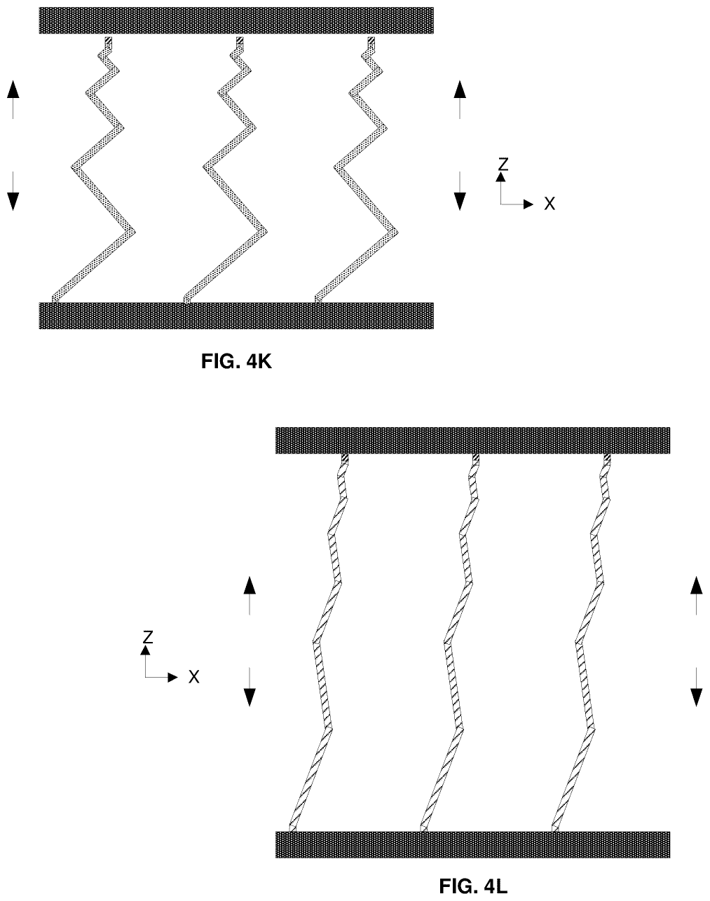

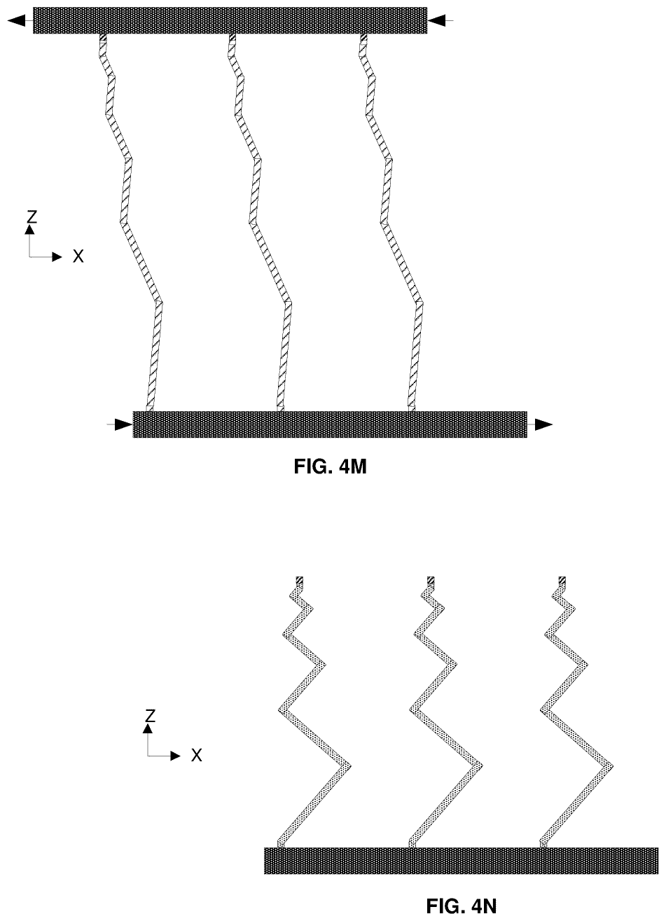

FIGS. 4A-4N illustrate an example probe array and various states in a process of forming the example probe array according to a specific embodiment of the invention using a combination of side views, cut side views, top views, and top cut views where the array has a plurality of probes having single spring elements that are laterally planar and have spiral configurations (prior to deformation) which are longitudinally deformed while in an array configuration to enhance probe length. FIG. 4A provides a side cut view showing three probes of the array after being longitudinally extended (i.e. plastically deformed). FIGS. 4B1 and 4B2 provide respective side cut and top cut views of an initially supplied substrate. FIGS. 4C1 and 4C2 provide respective side cut and top cut views of the substrate with a first layer formed thereon wherein the first layer shows nine probe or preform ends in an array configuration surrounded by a sacrificial material. FIGS. 4D1 and 4D2 provide respective side cut and top cut views of a second layer formed on the first layer wherein the second layer includes nine planar spiral spring elements with a left end portion of each attached to the probe or preform ends of the first layer, all of which are surrounded by a sacrificial material. FIGS. 4E1 and 4E2 provide respective side cut and top cut views of the substrate with a third layer formed on the second layer wherein the third layer shows probe or preform extension elements each connected to a central portion of the spiral spring elements of the second layer with all surrounded by a sacrificial material. FIGS. 4F1A and 4F2A show respective side cut and top cut views of a first optional formation of a last layer which includes probe or preform tip material on top of the structural material of the prior layer with each of the nine tips surrounded by sacrificial material while FIGS. 4F1B and 4F2B show respective side cut and top views of a second optional formation of the last layer where only the structural material is provided. FIGS. 4G1 to 4G3 show respective side cut, side, and top views of the example probes prior to deformation (i.e. the preforms) after removal of the sacrificial material from each layer in preparation for deformation. FIG. 4H provides a side cut view of three preform members of the probe array attached to the formation substrate while a deformation tool is laterally located above preforms but not yet contacting and attached. FIG. 4I provides a side cut view of the preform array after being contacted by the deformation tool and attached to the tool. FIG. 4J provides a side cut view of the probe preform array after an initial longitudinal separation of the substrate and tool to cause deformation of the spring elements including possible elastic and plastic deformation. FIG. 4K provides a side cut view of probe preforms after further separation of the substrate and tool and associated deformation of the spring elements including possible elastic and plastic deformation. FIG. 4L provides a side cut view of the probe preforms after still further longitudinal separation of the substrate and tool and associated deformation of the spring elements including possible elastic and plastic deformation. FIG. 4M provides a side cut view of the probe preforms after an optional lateral displacement of the deformation plate and the substrate to cause lateral deformation of the preforms in addition to previous longitudinal deformation that may include both elastic and plastic deformation. FIG. 4N provides a side cut view of the probe array after removal of the deformation tool (e.g. by allowing the deformation plate and substrate to return to an equilibrium position and release of any bonding agent or other retention mechanism that held the plate and probes together) wherein the probes have a desired elongated configuration with both ends of the probes in desired array configurations.

Numerous variations of the process illustrated in FIGS. 4A-4N are possible and include, for example: (1) arrays with different numbers of probes, (2) arrays with probes of non-uniform spacing, (3) arrays with probes having a plurality of different configurations, (4) probes with different initial (undeformed) relative spacings, (5) probes with different final (deformed) relative spacings, (6) probe arrays that include one or more guide plates that are engaged with the probe preforms or probes before or after formation or before or after deformation and before or after complete removal of sacrificial material wherein the guide plates may or may not function as deformation plates; (7) use of heat treatment and/or exposure to dopants or other chemicals at one or more points during the formation process, e.g. before or after deformation, to change the material properties of one or more preform or probe materials, or portions of such materials (e.g. to provide annealing, tempering, or hardening); (8) application of longitudinal and lateral displacements in different orders, in alternating stages, at different temperatures; (9) probes that are held to the substrate by dielectric material that adds in lateral or longitudinal retention during deformation and/or during use of the array; (10) probes that are released from the build substrate and attached to a different array substrate either before or after full or partial release from a sacrificial material and/or before or after longitudinal deformation; (11) probes that include a contact tip on each end without use of an permanent array substrate; (12) probes with multiple single-layer spring elements that are spaced from one another; (13) probes with non-planar spring elements; (14) probes that are laterally interlaced or overlapped while in the undeformed preform state and remain laterally interlaced or overlapped after deformation; (15) probes that are laterally interlaced or overlapped while in the undeformed preform state and are laterally separated after deformation; (16) probes that have spring elements that have non-lateral planar configurations, and/or (17) probes that have spring elements that are not laterally planar or planar within any plane that includes the longitudinal axis.

Other variations might allow different probes in the array to undergo different amounts of longitudinal and/or lateral deformation, for example, due to use of different probe preform designs, orientations, or the like; use of different materials in different portions of probes; use of different heat treatment conditions applied to different probes or portions of probes (e.g. by laser induced heating); use of deformation tools that allow attachment or temporary retention during deformation while allowing different amounts of lateral or longitudinal movement of selected probe preforms (e.g. using tools with holes of potentially different lateral sizes or shapes that engage probe elements to which a capping material is temporally added at potentially different longitudinal levels that allow retention of the probes by the tool and which allow differential displacement upon relative tool to substrate movement).

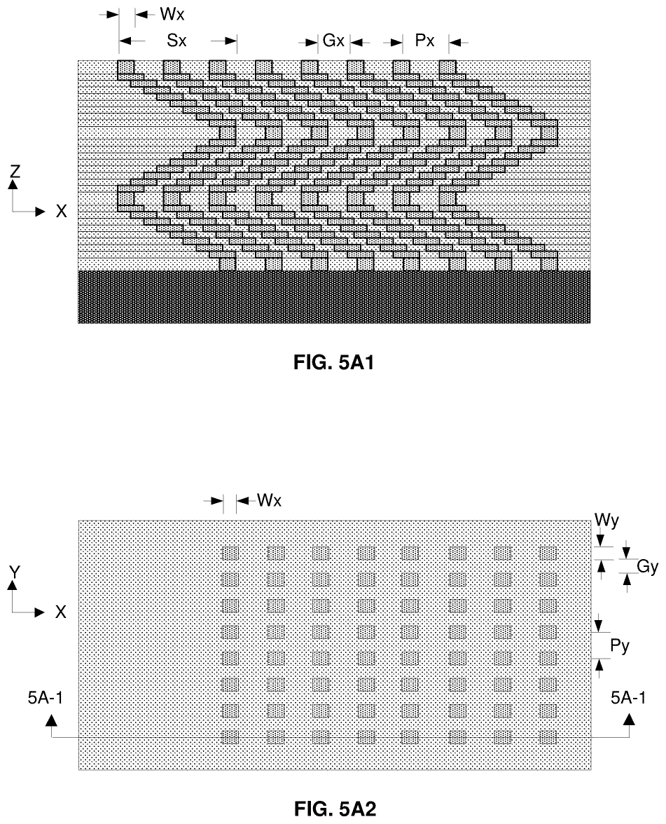

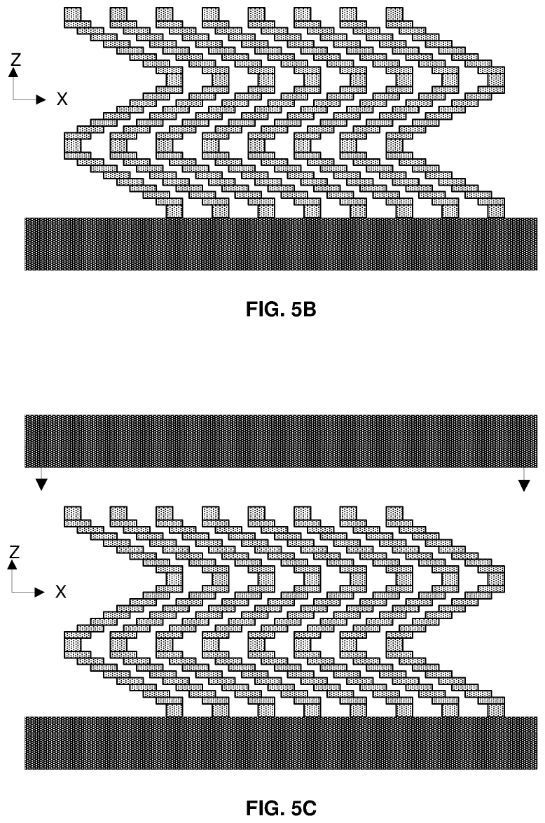

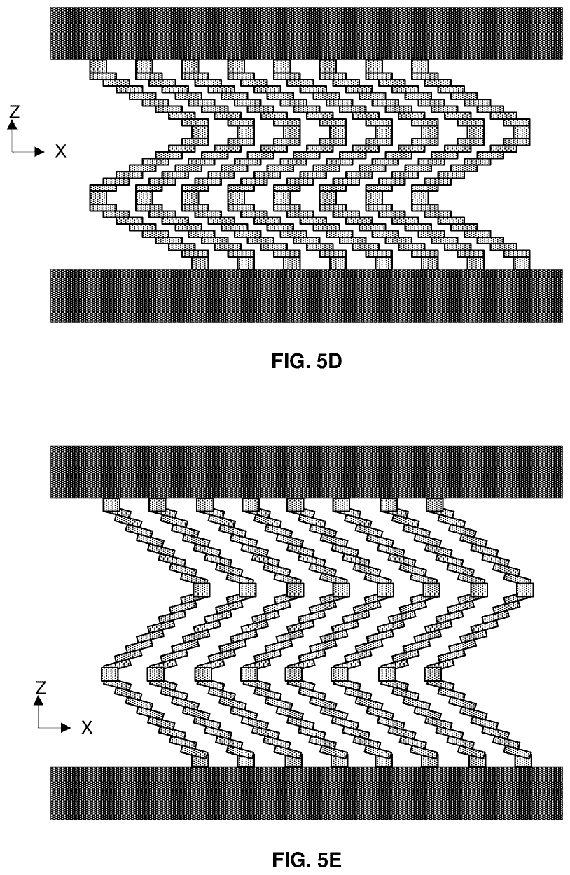

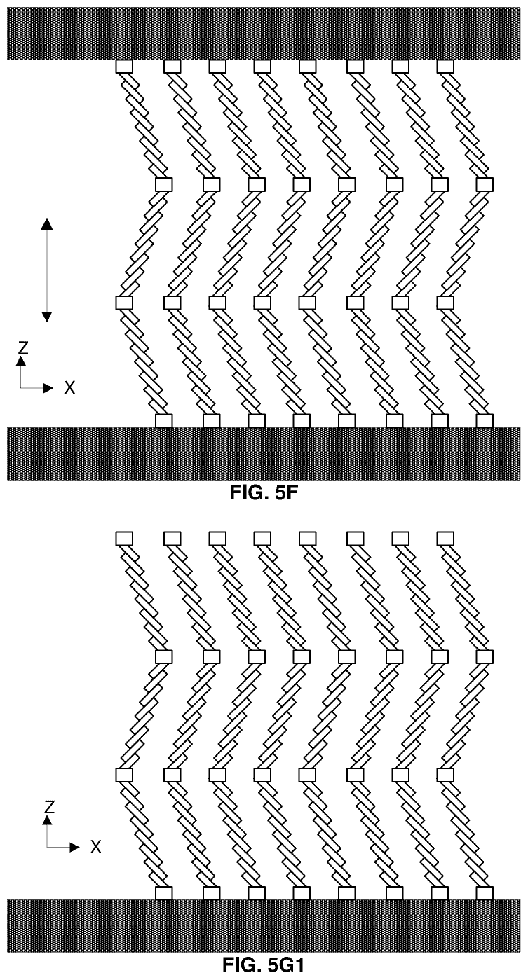

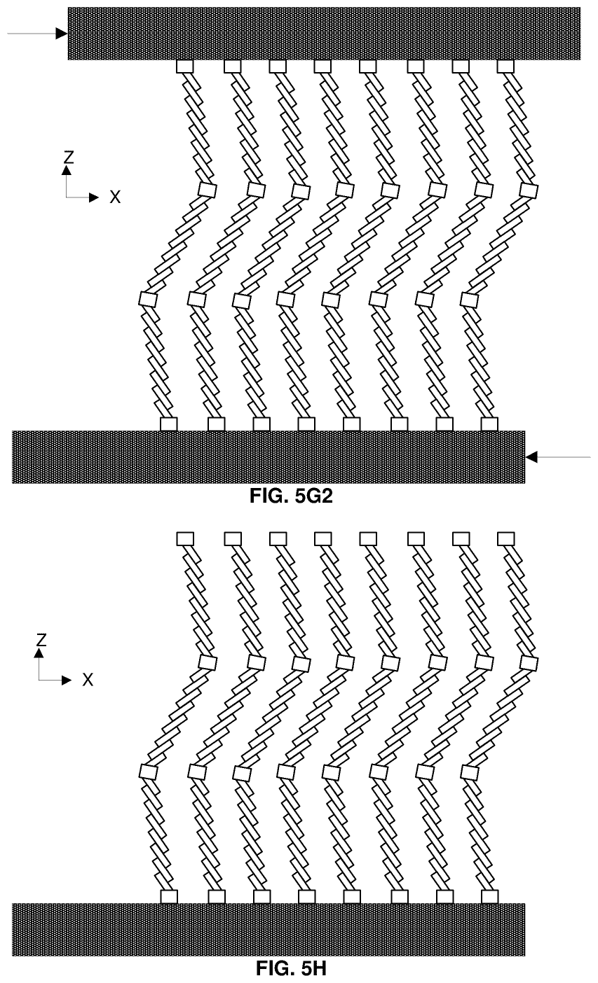

FIGS. 5A1-5H illustrate an example probe array and various states in a process of forming the example probe array according to another specific embodiment of the invention using a combination of cut side views and a top view where the array has a plurality of probes having three stages of angled stair-stepped spring elements located in series to form S-like inverted interlaced probes that start off as longitudinally compressed preforms (prior to deformation) which are longitudinally deformed while in an array configuration to enhance probe length and spacing between the probe bodies.

FIGS. 5A1 and 5A2 provide respective side cut and top views of an 8×8 array of probe preforms fabricated from 28 layers on a substrate with each layer including a structural material forming the probe preforms and a sacrificial material filling the rest of the layers. Some layers have different thicknesses compared to other layers (e.g. the layers where attachment to the substrate or to a deformation plate (see FIG. 5D) occur or stair-stepping changes directions are thicker than the layers where deformation is targeted). Each probe has nominal width Wx in the X-direction, the S-shape configuration of the preforms extending in the X-direction by an amount Sx, gaps between probes in the X-direction being Gx, and the pitch in the X-direction being Px. Each probe has nominal width Wy in the Y-direction, a flat configuration in Y of width Wy (i.e. the configuration has walls that extend in two Y-Z planes that are separated by Wy), gaps between probes in the Y-direction being Gy, and the pitch in the Y-direction being Gx. In some alternative embodiments, the parameters noted above may be modified, the probe preforms may be located in a non-uniform or incomplete array format, the preforms take on different design configurations or even multiple configurations in a single array. In some variations, the build substrate may be an array substrate while in others it may be a temporary substrate removed in favor of a different substrate and/or in favor of one or more guide plates.

FIG. 5B shows the state of the process from a side cut view looking at an X-Z plane after removal of the sacrificial material from each layer. In some alternative embodiments, a dielectric structural material may be applied as part of the first layer to help engage the probes and the substrate and hold them together (e.g. eliminating or reducing the use of a sacrificial material as part of the first layer). In some alternatives, controlled etching may be performed such that sacrificial material would be removed from the upper layers while more lower layers would temporarily maintain the sacrificial material, for example, as a stabilization material for one or more subsequent operations and thereafter removed. In still other alternatives, a different sacrificial material may be formed as part of one or more lower layers such that upon removal of sacrificial material from the upper layers, sacrificial material on the bottom layer or layers may be retained at least temporarily for certain process operations (e.g. for stabilization during deformation) and thereafter removed.

FIG. 5C shows a side cut view of a state of the process after a deformation plate has been located laterally above the array but not yet longitudinally contacted with the upper ends of the probe preforms. In some alternatives, the deformation plate may be made to contact and attach to the probe preforms prior to removal of any or all of sacrificial material or after removal of only a portion of the sacrificial material. In some alternative embodiments, the deformation plate may have openings into which the probe ends may be located or pass completely through, and in some alternatives, the deformation plate may include laterally movable elements that may grasp the probe preforms to engage them. In other alternatives, the deformation plate may have a sacrificial capping material deposited or applied after insertion of the probe ends to bond the probe ends and the plate temporarily to one another.

FIG. 5D shows a side cut view of a state of the process after a deformation plate has been contacted and attached or otherwise engaged with the probe preforms. In some alternatives, a sacrificial material may have been retained around one or more of the upper layers (e.g. the top one or more layers or one or more layers below one or more of the top layers when those one or more top layers are to be inserted into openings in a deformation plate) to aid in the process of attaching, engaging, and or stabilizing the connection between the deformation plate and the preforms. In other alternatives, the build substrate may also be removed and replaced by a permanent substrate or a second deformation plate.

FIGS. 5E and 5F show side cut views of states of the process after first and second amounts of longitudinal elongation of the probe preforms by expanding longitudinal (e.g. Z-direction) separation of the deformation plate and the guide plate.

FIGS. 5G1 and 5G2 show side cut views of two alternative next states of the process where the deformation plate is removed to yield a final processing state (FIG. 5G1) or where the deformation plate is retained and undergoes lateral movement relative to the substrate to produce probes with both longitudinal and lateral plastic deformation.

FIG. 5H shows a side cut view of a final state of processing after removal of the deformation plate follows the lateral offset that yielded the state of FIG. 5G2. Alternative processes may implement the processes of FIGS. 5E-5H in different orders or in a plurality of substeps involving multiple smaller longitudinal movements and lateral movements.

Numerous other alternatives to the general embodiments of FIGS. 2 and 3 and the specific embodiments of FIGS. 4A-4N and 5A-5H are possible, some of which have been noted above while others may involve a number of potential process tools, structures, operations, steps, or groups of steps (i.e. process elements) that may be used or performed in various combinations or sub-combinations. Depending on the specific process implementation being used, these process elements may be used or performed in series or perhaps even in parallel. In some process implementations, the order of usage or performing process elements may be varied. In some implementations, individual process elements may be used or implemented in different ways and may include use of one or more tools, structures, process steps, or operations which may in turn be performed in series, perhaps in parallel, and perhaps using varying orders of operations.

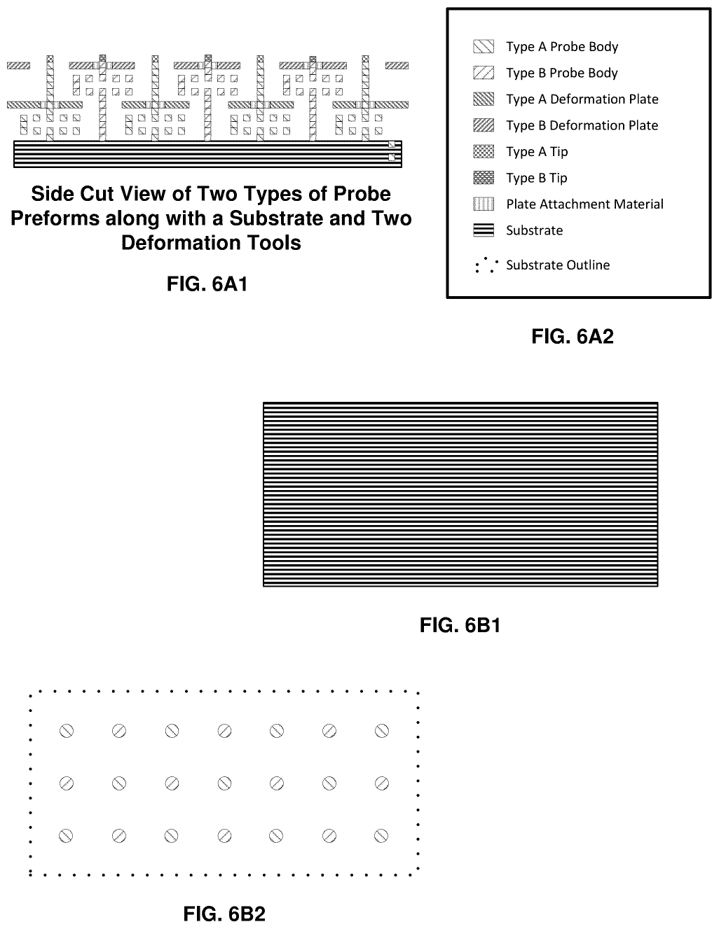

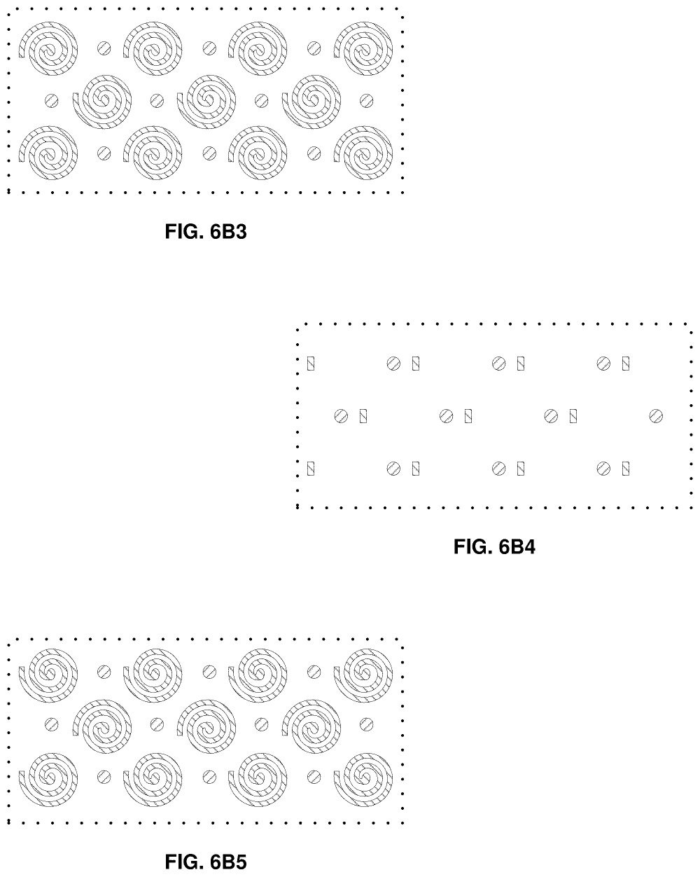

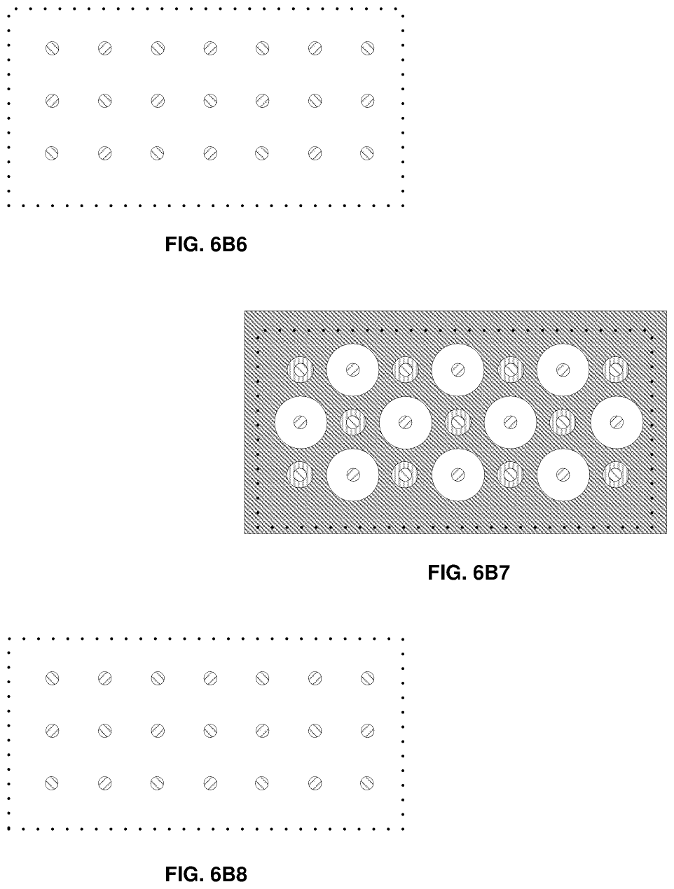

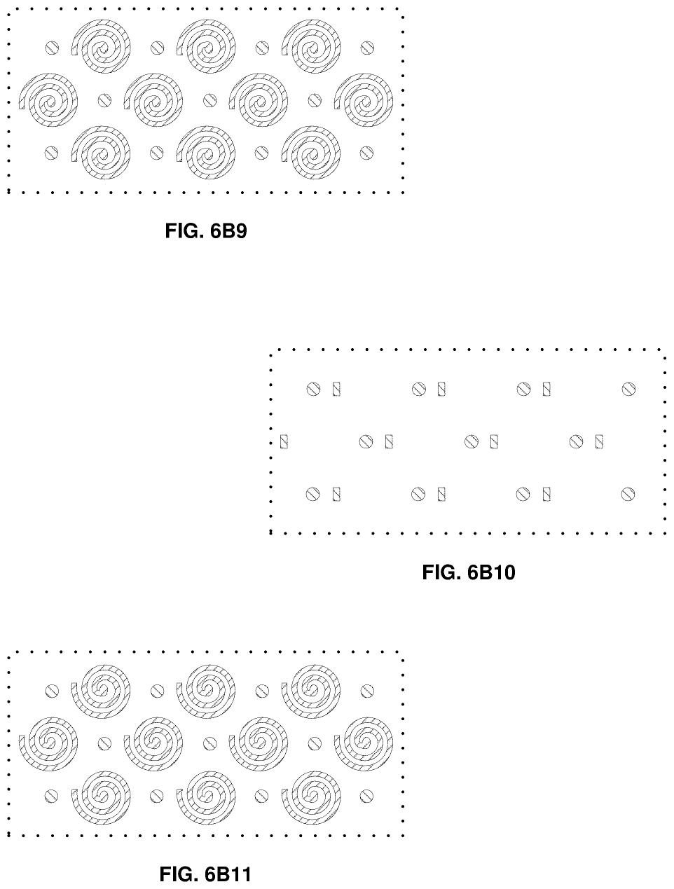

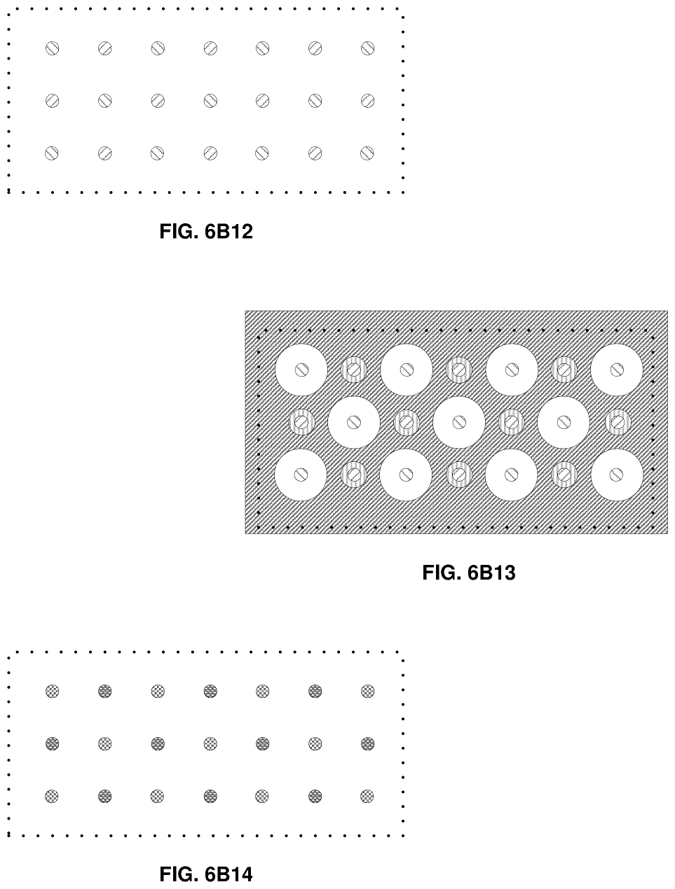

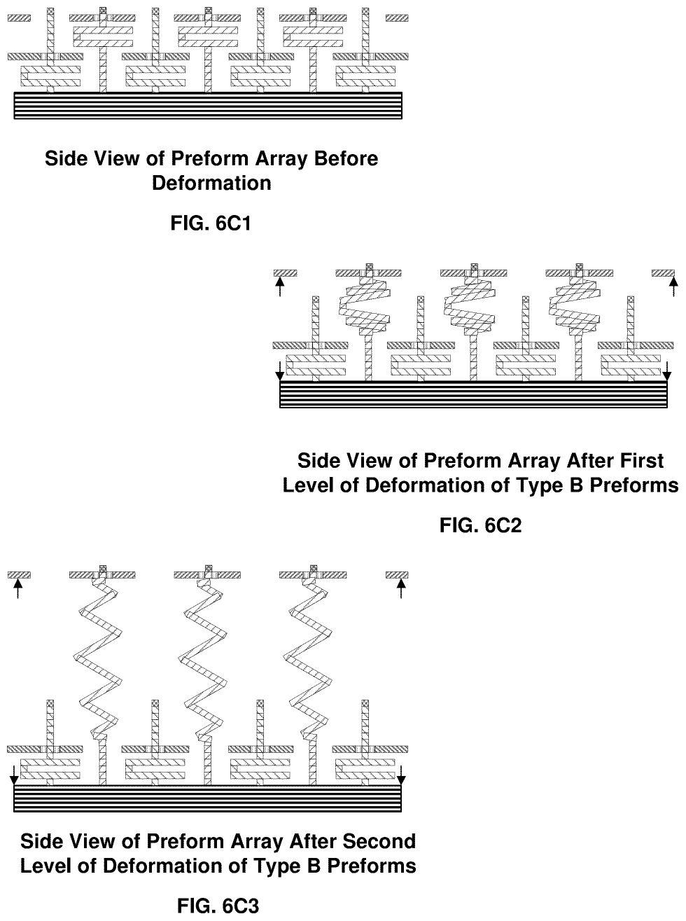

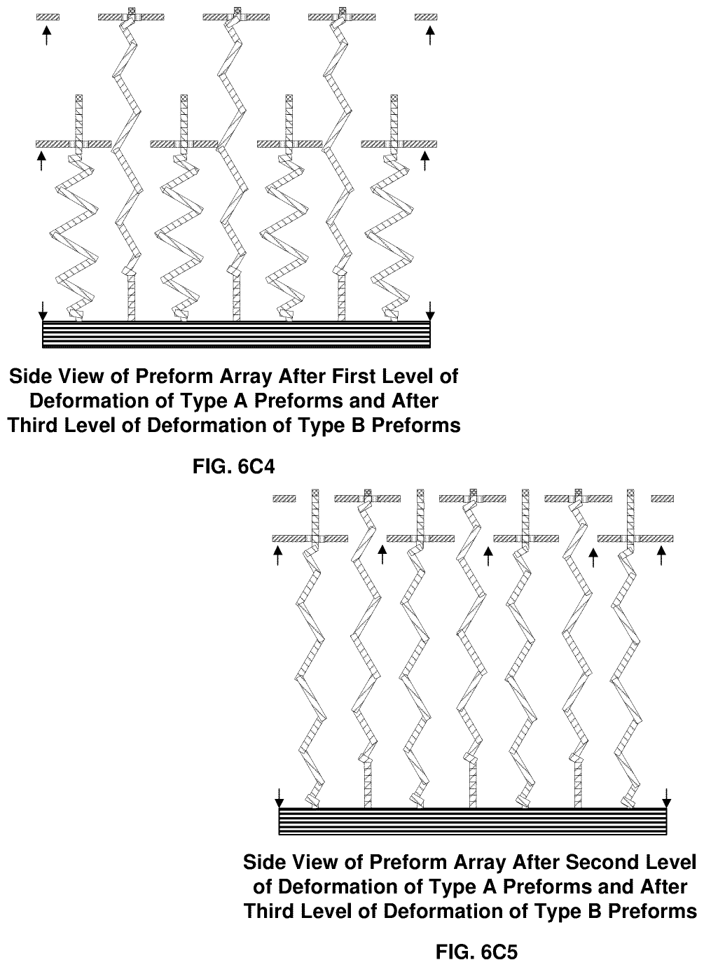

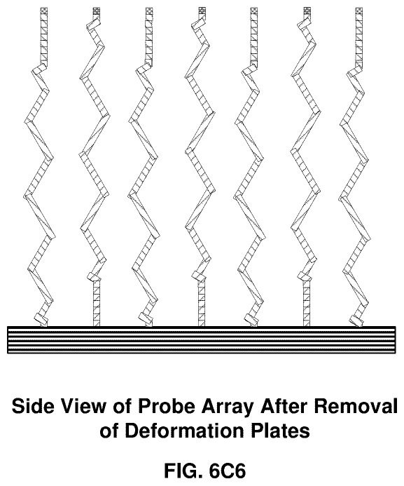

FIGS. 6A1-6C6 illustrate an example probe array and various states in a process of forming the probe array according to another specific embodiment of the invention using a combination of a cut side view of an array preform and deformation tools, as formed or positioned, but without showing sacrificial material (FIG. 6A1), a table providing a legend or key to hatching patterns used in the illustrations (FIG. 6A2), top views of successively formed layers of the preform array and deformation tools, including a substrate outline for maintaining lateral registration perspective from layer-to-layer (FIGS. 6B1-6B14), side views of the probe preform array as it transitions through various levels of deformation from an undeformed array to a fully deformed array wherein deformation occurs on a probe group-by-probe group basis to minimize risk of collisions of partially overlapping preforms (FIGS. 6C1-6C5), and side view of a final array after deformation and removal of deformation tools (FIG. 6C6).

In some variations different orders and patterns of deformation may have been used. In some variations one or both of the deformation tools may have been retained as guide plates, perhaps upon bringing them into joined contact and longitudinal, and or lateral, movement to a desired guide plate location. As with the other specific embodiments, numerous other variations are possible and include use of probe preforms having other initial configurations or preform-to-preform spacings, whether periodic or aperiodic or uniform with no missing preforms or uniform with missing preforms, different numbers of stacked planar coils, non-planar coils, different diameters of stacked planar coils different extents of overlap of different types of preforms, use of additional groups of preforms, use of different probe spacing patterns within a type, use of different array patterns between types, use of different number of preforms, use of linear arrays as well as two-dimensional arrays, formation of arrays with probes having different tip heights, use of different amounts of deformation, use of lateral movements to cause temporary elastic deformation or plastic deformation to help preforms slide passed one another during deformation, and the like. Other variations include those set forth herein in the aspects, in the variations of the aspects, in the other embodiments, or in the variations to the other embodiments with changes made as necessary.

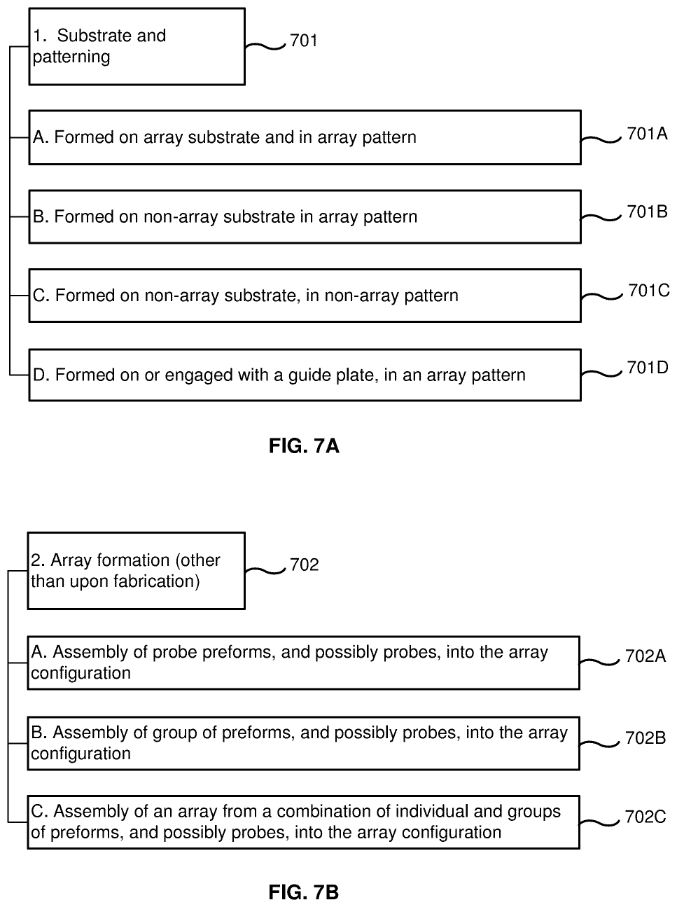

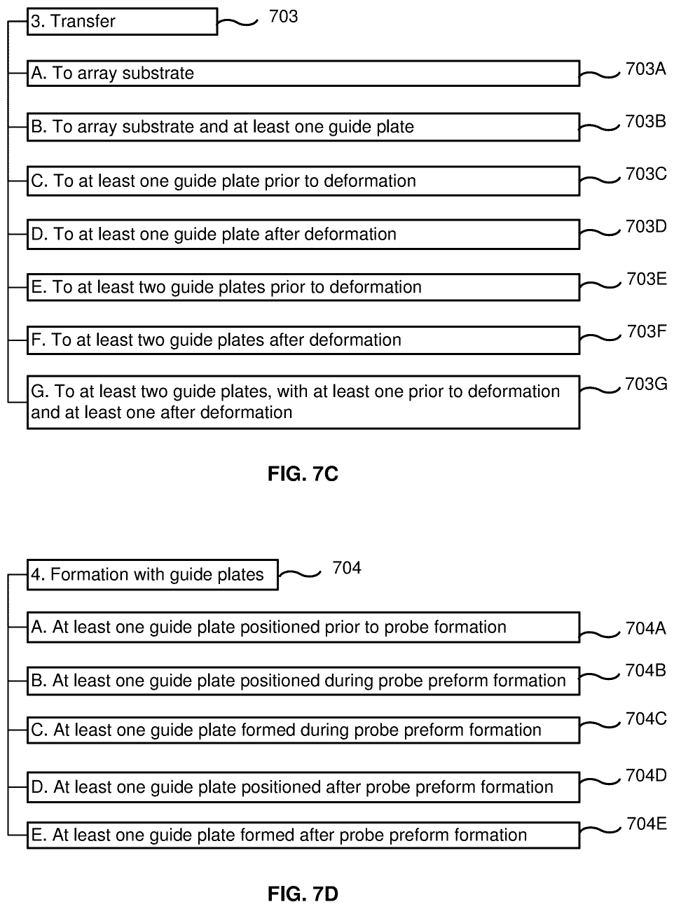

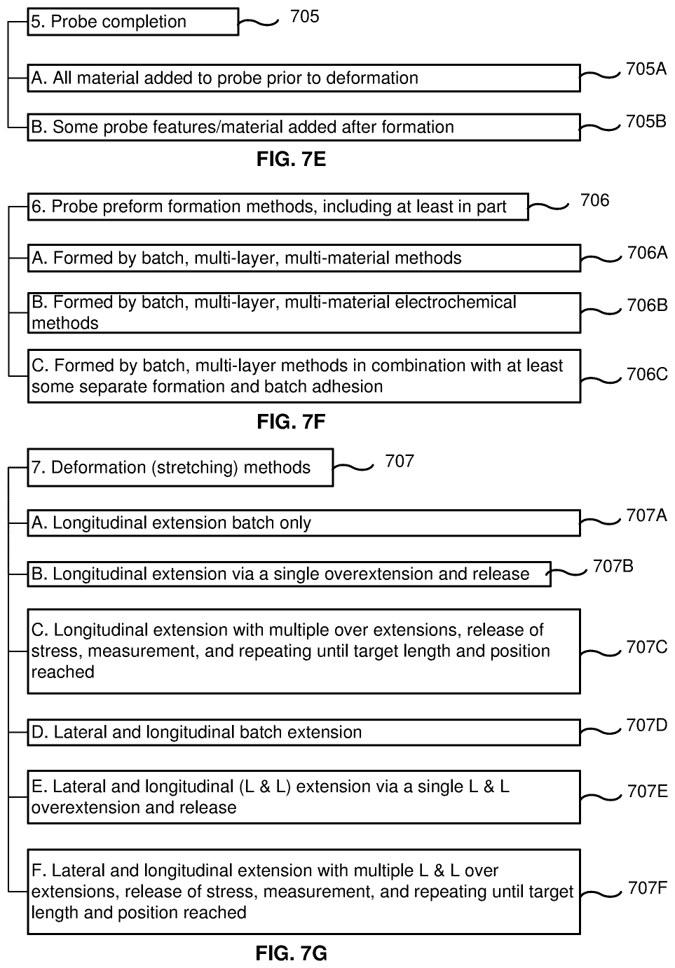

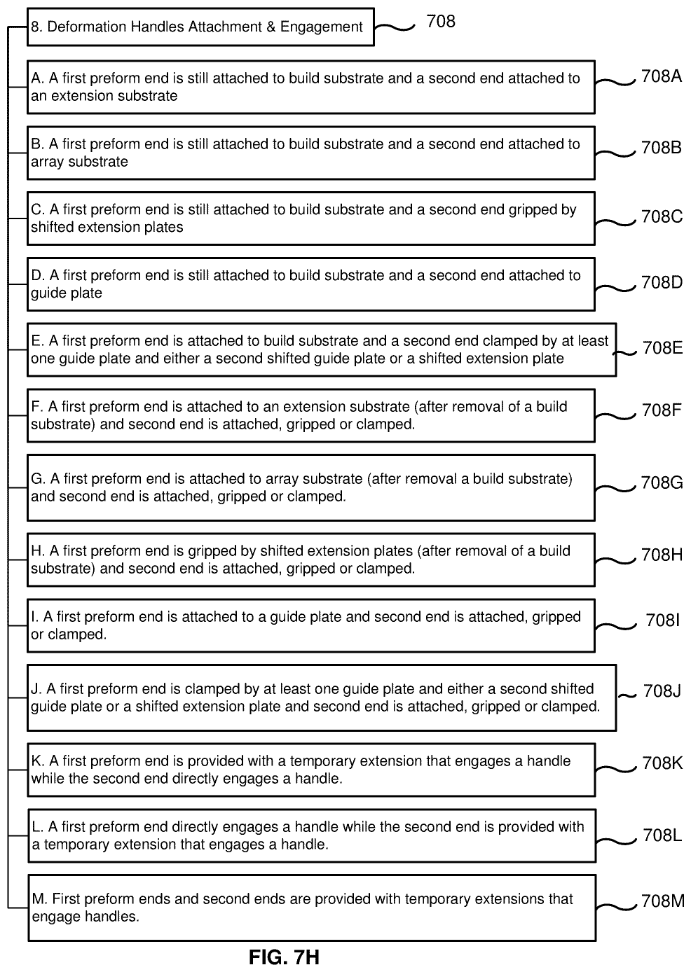

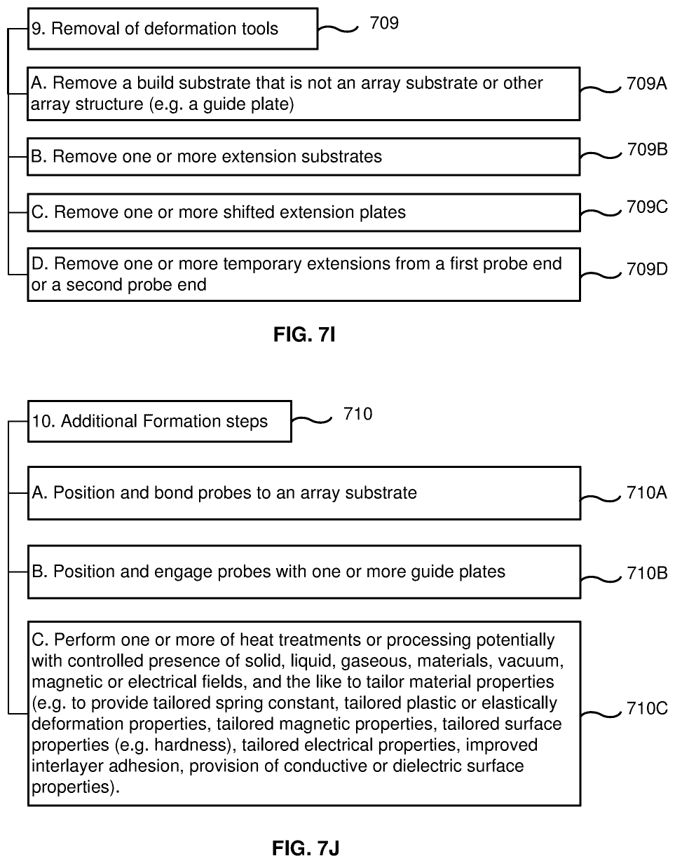

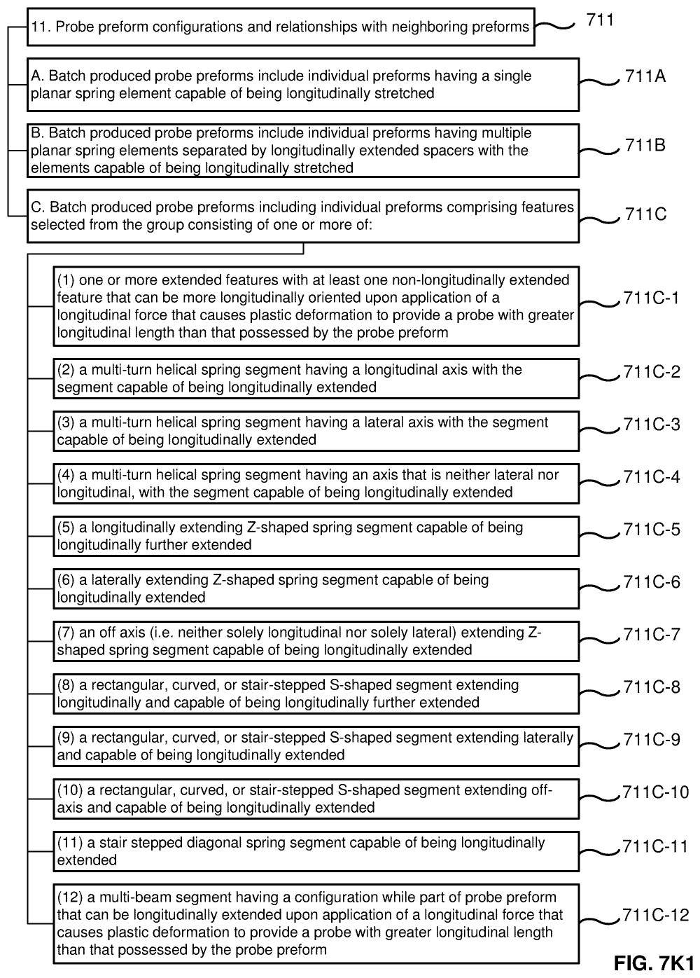

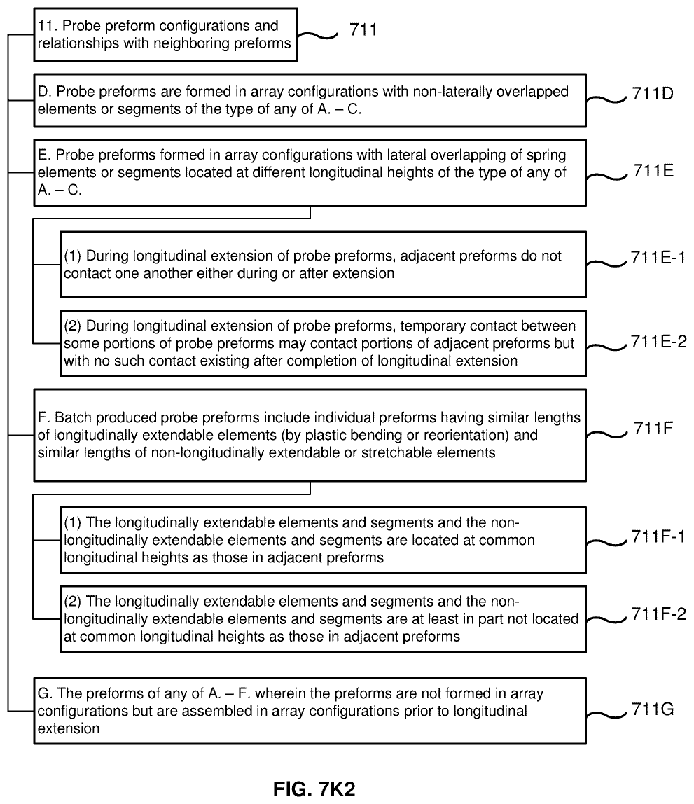

FIGS. 7A-7K2 provide block diagrams of example process elements and/or variables that may be used in alternative embodiments of the invention along with some sample values or variations that the element or variable might take.

FIG. 7A provides a block diagram 701 that sets forth generalized examples of build substrates and probe preform patterns that may be used in various alternative embodiments of the invention. In generic terms, a substrate may take any of forms including, for example: (1) an array substrate (i.e. a substrate that will form part of the array structure when the array is completed, e.g. a space transformer, an interposer substrate, a via substrate, or other substrate with patterned conductive paths), (2) a non-array substrate (i.e. a build substrate that temporarily holds the probes during formation but which is removed in whole or in part prior to putting a probe array to use), e.g. a metal substrate, ceramic substrate, a conductive substrate, a dielectric substrate, or a dielectric substrate wherein the substrate may include a seed layer and/or a release layer located thereon, or (3) a supported or unsupported guide plate or guide plates with through holes, or through hole locations into, or onto, which probe preforms are affixed during probe preform fabrication and which may be opened after complete or partial probe preform formation to allow longitudinal motion of probe preforms or probes relative and the guide plate(s). In generic terms, probe formation patterns on the substrate may take a variety of forms including, for example: (1) a two-dimensional probe array distribution pattern with or without uniform spacing of probes but with probe tips or probe bases located relative to one another in the array pattern, (2) a distribution pattern that allows a desirable building density in combination with ready separation from the substrate either in bulk or by picking and placing, i.e. in any desirable build configuration, without regard to an array configuration, or (3) in groups of probe preforms with probes in each group having an array configuration but with probes in different groups not necessarily being arranged in a larger array configuration, e.g. each individual group might consist of a configuration corresponding to a pattern of test pads on a single DUT that will undergo testing or a pattern consisting of a configuration corresponding to test pads for portions of neighboring DUTS, and/or a pattern corresponding to a contact pad pattern of a space transformer or a guide plate hole pattern. In some variations probe tips (e.g., tips that will contact a DUT) may be in contact the build substrate or may be located away from substrate. When probe tips are formed in contact with the build substrate, direct bonding of a space transformer to the opposite sides of the probes (or preforms) can occur prior to releasing the build substrate. Alternatively, when formed with the tips away from the substrate, mounting to a space transformer or engaging another array element might require removal of the build substrate first.

Elements 701A-701D list examples of specific substrate and patterning combinations. Element 701A provides for probe preforms, and possibly probes, being formed on an array substrate in an array pattern.

Element 701B provides for probe preforms, or probes, being formed on a non-array substrate but with the probe preforms, or probes, formed in an array pattern such that probe preforms, or probes, themselves may be removed from the substrate. In embodiments involving Element 701B, various follow up operations may occur to engage the arrayed probe preforms, or probes, with an array substrate or guide plates. For example, the build substrate may be separated from the arrayed probe preforms, or probes, before or after transferring the probe preforms, or probes, to an array substrate either of which may occur before or after removal of a sacrificial material that holds the probe preforms or probes in their relative positions. In another alternative, during probe preform, or probe, formation the probe preforms, or probes, may be formed around or made to engage guide plates which may be used to retain the probes in their array configuration after removal of the substrate. In still another alternative, probe preforms, or probes, after formation may be made to engage with one or more guide plates or other retention structures before or after the non-array substrate is removed.

Element 701C provides for the formation of probe preforms or probes on a non-array substrate with a non-array pattern. In such embodiments, some groups of probes may be formed with an array spacing, which may be retained until transfer to another alignment structure or engagement with retention structures occurs (e.g. transfer to an array substrate and/or guide plates) while in other embodiments, probes may be released from the substrate in bulk or one at time, followed by individual placement on an array substrate or into an alignment pattern for engagement with one or more guide plates.

Element 701D provides for the formation of probe preforms or probes in an array pattern while engaging one or more guide plates where one or more guide plates may function as a build substrate with or without a first end of some probes bonded to a material filling the through holes of a guide plate or with one or more through holes being filled by a combination of a filler material and a portion of each probe that is formed within or moved into the holes.

FIG. 7B provides a block diagram that sets forth generalized examples of array formation when probes are not already formed in array patterns. Element 702A provides for assembly of probe preforms, or possibly probes, into an array configuration, e.g., using picking and placing, either before or after partial or complete longitudinal extension of the preforms, and subsequent bonding to an array substrate. Alternatively, placement may locate the preforms or probes directly into openings in guide plates or other retention structures. In some variations, preforms may be elongated (longitudinally extended) and, if necessary, laterally displaced using the substrates and/or guide plates or other retention structures as deformation tools wherein movement may provide for plastic deformation alone or plastic deformation in combination with some elastic deformation wherein some elastic deformation may be retained in a final array configuration or may be eliminated, for example, by reversing a portion of the motion that led to the initial deformation. Element 702B is similar to element 702A but where assembly of probe arrays occurs by placement of multiple groups of probes onto an array substrate or upon engagement with array retention structures wherein individual groups include multiple probes that are held in a subarray configuration (e.g. by retention of an intermediate sacrificial material that holds the group of probes in a desired relationship, attachment to a subarray substrate or engagement with one or more subarray retention structures prior to placement on an array substrate or in array retention structures, or possibly by inclusion of tethers that connect the probes to one another where the tethers, if dielectric may be retained, or may be cut away after engagement with other array retention structures). Element 702C provides for an assembly by a combination of 702A and 702B.

FIG. 7C provides a block diagram 703 that sets forth probe array transfer examples of build substrates that are removed in favor of array substrates, guide plates, or combination of the two where transfer may occur prior to or after deformation of the probe preforms. Element 703A provides for the transfer to an array substrate. Element 703B provides for the transfer to an array substrate and at least one guide plate. Element 703C provides for the transfer to at least one guide plate prior to deformation. Element 703D provides for the transfer to at least one guide plate after deformation. Element 703E provides for the transfer to at least two guide plates prior to deformation. Element 703F provides for the transfer to at least two guide plates after deformation. Element 603G provides for the transfer to at least two guide plates, with at least one prior to deformation and at least one after deformation.

FIG. 7D provides a block diagram 704 that sets forth examples of guide plate incorporation into arrays of preforms either prior to, during, or after probe preform formation. Element 704A provides for guide plate incorporation including at least one guide plate positioned prior to probe formation. Element 704B provides for guide plate incorporation including at least one guide plate positioned during probe preform formation. Element 704C provides for guide plate incorporation including at least one guide plate formed during probe preform formation. Element 704D provides for guide plate incorporation including at least one guide plate positioned after probe preform formation. Element 704E provides for guide plate incorporation including at least one guide plate formed after probe preform formation.

FIG. 7E provides a block diagram 705 that illustrates different example relationships that are possible relating to probe feature formation and deformation. Element 705A provides for probe completion in which all material is added to probes prior to deformation. Element 705B provides for probe completion in which some probe features/material are added after formation.

FIG. 7F provides a block diagram 706 illustrating different examples of probe preform formation methods. Element 706A provides for probe preform formation, including at least in part, by batch, multi-layer, multi-material methods. Element 706B provides for probe preform formation, including at least in part, by batch, multi-layer, multi-material electrochemical methods. Element 706C provides for probe preform formation, including at least in part, by batch, multi-layer methods in combination with at least some separate formation and batch adhesion.

FIG. 7G provides a block diagram 707 that sets forth different example deformation methods that involve longitudinal extension or a combination of longitudinal and lateral (L & L) extension. Element 707A provides for deformation (stretching) methods including longitudinal extension in a batch process. Element 707B provides for deformation (stretching) methods including longitudinal extension via a single overextension and release. Element 707C provides for deformation (stretching) methods including longitudinal extension with multiple over extensions, release of stress, measurement, and repeating until target length and position reached. Element 707D provides for deformation (stretching) methods including lateral and longitudinal batch extension. Element 707E provides for deformation (stretching) methods including lateral and longitudinal extension via a single L & L overextension and release. Element 707F provides for deformation (stretching) methods including lateral and longitudinal extension with multiple L & L over extensions, release of stress, measurement, and repeating until target length and position reached.

FIG. 7H provides a block diagram 708 that sets forth different examples of deformation tools (extension substrate or deformation plates, guide plates, handles) and attachment methods. Element 708A provides for attachment and engagement using deformation handles (gripping or attachment locations) where a first preform end is attached to a build substrate and a second is attached to an extension substrate. Element 7086 provides for attachment and engagement using deformation handles in which a first preform end is still attached to a build substrate and a second end is attached to an array substrate. Element 708C provides for attachment and engagement using deformation handles in which a first preform end is still attached to a build substrate and a second end is gripped by shifted extension plates. Element 708D provides for attachment and engagement using deformation handles in which a first preform end is still attached to a build substrate and a second end is attached to a guide plate. Element 708E provides for attachment and engagement using deformation handles in which a first preform end is still attached to a build substrate and a second end is clamped by at least one guide plate and either a second shifted guide plate or a shifted extension plate. Element 708F provides for attachment and engagement using deformation handles in which a first preform end is attached to an extension substrate (after removal of a build substrate) and a second end is attached, gripped or clamped. Element 708G provides for attachment and engagement using deformation handles in which a first preform end is attached to an array substrate (after removal a build substrate) and a second end is attached, gripped or clamped. Element 708H provides for attachment and engagement using deformation handles in which a first preform end is gripped by shifted extension plates (after removal of a build substrate) and a second end is attached, gripped or clamped. Element 708I provides for attachment and engagement using deformation handles in which a first preform end is attached to a guide plate and a second end is attached, gripped or clamped. Element 708J provides for attachment and engagement using deformation handles in which a first preform end is clamped by at least one guide plate and either a second shifted guide plate or a shifted extension plate and a second end is attached, gripped or clamped. Element 708K provides for attachment and engagement using deformation handles in which a first preform end is provided with a temporary extension that engages a handle while a second end directly engages a handle. Element 708L provides for attachment and engagement using deformation handles in which a first preform end directly engages a handle while a second end is provided with a temporary extension that engages a handle. Element 708M provides for attachment and engagement using deformation handles in which first preform ends and second ends are provided with temporary extensions that engage handles.

FIG. 7I provides a block diagram 709 that sets forth examples of removing deformation tools. Element 709A provides for removal of deformation tools including removing a build substrate that is not an array substrate or other array structure (e.g. a guide plate). Element 709B provides for removal of deformation tools including removing one or more extension substrates. Element 709C provides for removal of deformation tools including removing one or more shifted extension plates. Element 709D provides for removal of deformation tools including removing one or more temporary extensions from a first probe end or a second probe end.

FIG. 7J provides a block diagram 710 that sets forth some additional formation steps. Element 710A provides for additional formation steps including positioning and bonding probes to an array substrate. Element 710B provides for additional formation steps including positioning and engaging probes with one or more guide plates. Element 710C provides for additional formation steps including performing one or more of heat treatments or processing potentially with controlled presence of solid, liquid, gaseous, materials, vacuum, magnetic or electrical fields, and the like to tailor material properties (e.g. to provide tailored spring constant, tailored plastic or elastically deformation properties, tailored magnetic properties, tailored surface properties (e.g. hardness), tailored electrical properties, improved interlayer adhesion, provision of conductive or dielectric surface properties).

FIG. 7K1 provides a block diagram 711 that sets forth a first group of example probe preform configurations and relationships with neighboring preforms. Element 711A provides for batch produced probe preforms including individual preforms having a single planar spring element capable of being longitudinally stretched. Element 711B provides for batch produced probe preforms including individual preforms having multiple planar spring elements separated by longitudinally extended spacers with the elements capable of being longitudinally stretched. Element 711C provides for batch produced probe preforms including individual preforms including features selected from the group consisting of one or more elements C1 to C12. Element 71101 which provides for one or more extended features with at least one non-longitudinally extended feature that can be more longitudinally oriented upon application of a longitudinal force that causes plastic deformation to provide a probe with greater longitudinal length than that possessed by the probe preform. Element 71102 which provides for a multi-turn helical spring segment having a longitudinal axis with the segment capable of being longitudinally extended. Element 711C3 which provides for a multi-turn helical spring segment having a lateral axis with the segment capable of being longitudinally extended. Element 711C4 which provides for a multi-turn helical spring segment having an axis that is neither lateral nor longitudinal, with the segment capable of being longitudinally extended. Element 711C5 which provides for a longitudinally extending Z-shaped spring segment capable of being longitudinally further extended. Element 71106 which provides for a laterally extending Z-shaped spring segment capable of being longitudinally extended. Element 711C7 which provides for an off axis (i.e. neither solely longitudinal nor solely lateral) extending Z-shaped spring segment capable of being longitudinally extended. Element 711C8 which provides for a rectangular, curved, or stair-stepped S-shaped segment extending longitudinally and capable of being longitudinally further extended. Element 711C9 which provides for a rectangular, curved, or stair-stepped S-shaped segment extending laterally and capable of being longitudinally extended. Element 711C10 which provides for a rectangular, curved, or stair-stepped S-shaped segment extending off-axis and capable of being longitudinally extended. Element 711C11 which provides for a stair stepped diagonal spring segment capable of being longitudinally extended. Element 711C12 which provides for a multi-beam segment having a configuration while part of a probe preform can be longitudinally extended upon application of a longitudinal force that causes plastic deformation to provide a probe with greater longitudinal length than that possessed by the probe preform.

FIG. 7K2 provides a continuation of block diagram 711 that set forth a second group of example probe preform configurations and relationships with neighboring preforms. Element 711D provides for probe preforms being formed in array configurations with non-laterally overlapped elements or segments of the type of 711A-711C. Element 711E provides for probe preforms being formed in array configurations with lateral overlapping of spring elements or segments located at different longitudinal heights of the type of any of 711A-711C. Element 711E1 provides for, during longitudinal extension of probe preforms, adjacent preforms not contacting one another either during or after extension. Element 711E2 provides for, during longitudinal extension of probe preforms, temporary contact between some portions of probe preforms possibly contacting portions of adjacent preforms but with no such contact existing after completion of longitudinal extension. Element 711F provides for batch produced probe preforms including individual preforms having similar lengths of longitudinally extendable elements (by plastic bending or reorientation) and similar lengths of non-longitudinally extendable stretchable elements. Element 711 F1 provides for the longitudinally extendable elements and segments and the non-longitudinally extendable elements and segments being located at common longitudinal heights as those in adjacent preforms. Element 711 F2 provides for the longitudinally extendable elements and segments and the non-longitudinally extendable elements and segments being at least in part not located at common longitudinal heights as those in adjacent preforms. Element 711G provides for the preforms of any of 711A-711F wherein the preforms are not formed in array configurations but are assembled in array configurations prior to longitudinal extension.

Further Comments and Conclusions

Various other embodiments of the present invention exist. Some of these embodiments may be based on a combination of the teachings herein with various teachings incorporated herein by reference. For example, some fabrication embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, palladium-cobalt, silver, molybdenum, manganese, brass, chrome, chromium copper (Cr—Cu), and combinations of these while still other materials are functional and useable. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder, or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials or as sacrificial materials.

Structural or sacrificial dielectric materials may be incorporated into embodiments of the present invention in a variety of different ways. Such materials may form a third material or higher deposited material on selected layers or may form one of the first two materials deposited on some layers. Additional teachings concerning the formation of structures on dielectric substrates and/or the formation of structures that incorporate dielectric materials into the formation process and possibility into the final structures as formed are set forth in a number of patent applications filed Dec. 31, 2003: (1) U.S. Patent Application No. 60/534,184 which is entitled “Electrochemical Fabrication Methods Incorporating Dielectric Materials and/or Using Dielectric Substrates”; (2) U.S. Patent Application No. 60/533,932, which is entitled “Electrochemical Fabrication Methods Using Dielectric Substrates”; (3) U.S. Patent Application No. 60/534,157, which is entitled “Electrochemical Fabrication Methods Incorporating Dielectric Materials”; (4) U.S. Patent Application No. 60/533,891, which is entitled “Methods for Electrochemically Fabricating Structures Incorporating Dielectric Sheets and/or Seed layers That Are Partially Removed Via Planarization”; and (5) U.S. Patent Application No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into electrochemical fabrication processes include: (1) U.S. patent application Ser. No. 11/139,262, filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216, filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (6) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (7) U.S. patent application Ser. No. 10/607,931, by Brown, et al., which was filed on Jun. 27, 2003, now U.S. Pat. No. 7,239,219, and which is entitled “Miniature RF and Microwave Components and Methods for Fabricating Such Components”, (8) U.S. patent application Ser. No. 10/841,006, by Thompson, et al., which was filed on May 7, 2004, now abandoned, and which is entitled “Electrochemically Fabricated Structures Having Dielectric or Active Bases and Methods of and Apparatus for Producing Such Structures”; (9) U.S. patent application Ser. No. 10/434,295, by Cohen, which was filed on May 7, 2003, now abandoned, and which is entitled “Method of and Apparatus for Forming Three-Dimensional Structures Integral With Semiconductor Based Circuitry”; and (10) U.S. patent application Ser. No. 10/677,556, by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,384 which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, enhanced methods of using may be implemented, and the like.

| U.S. Pat App No., Filing Date | |
|---|---|
| U.S. App Pub No., Pub Date | |
| U.S. Patent No., Pub Date | First Named Inventor, Title |
| 10/271,574 - Oct. 15, 2002 | Cohen, “Methods of and Apparatus for Making High |
| 2003-0127336 - Jul. 10, 2003 | Aspect Ratio Microelectromechanical Structures” |
| 7,288,178 - Oct. 30, 2007 | |
| 10/387,958 - Mar. 13, 2003 | Cohen, “Electrochemical Fabrication Method and |
| 2003-022168 - Dec. 4, 2003 | Application for Producing Three-Dimensional Structures |
| — | Having Improved Surface Finish” |
| 10/434,289 - May 7, 2003 | Zhang, “Conformable Contact Masking Methods and |
| 20040065555 - Apr. 8, 2004 | Apparatus Utilizing In Situ Cathodic Activation of a |
| — | Substrate” |
| 10/434,294 - May 7, 2003 | Zhang, “Electrochemical Fabrication Methods With |
| 2004-0065550 - Apr. 8, 2004 | Enhanced Post Deposition Processing” |
| — | |
| 10/434,315 - May 7, 2003 | Bang, “Methods of and Apparatus for Molding Structures |
| 2003-0234179 - Dec. 25, 2003 | Using Sacrificial Metal Patterns” |
| 7,229,542 - Jun. 12, 2007 | |
| 10/434,494 - May 7, 2003 | Zhang, “Methods and Apparatus for Monitoring |
| 2004-0000489 - Jan. 1, 2004 | Deposition Quality During Conformable Contact Mask |
| — | Plating Operations” |
| 10/677,498 - Oct. 1, 2003 | Cohen, “Multi-cell Masks and Methods and Apparatus for |
| 2004-0134788 - Jul. 15, 2004 | Using Such Masks To Form Three-Dimensional |
| 7,235,166 - Jun. 26, 2007 | Structures” |
| 10/697,597 - Dec. 20, 2002 | Lockard, “EFAB Methods and Apparatus Including Spray |
| 2004-0146650 - Jul. 29, 2004 | Metal or Powder Coating Processes” |
| — | |
| 10/724,513 - Nov. 26, 2003 | Cohen, “Non-Conformable Masks and Methods and |
| 2004-0147124 - Jul. 29, 2004 | Apparatus for Forming Three-Dimensional Structures” |
| 7,368,044 - May 6, 2008 | |
| 10/724,515 - Nov. 26, 2003 | Cohen, “Method for Electrochemically Forming Structures |
| 2004-0182716 - Sep. 23, 2004 | Including Non-Parallel Mating of Contact Masks and |
| 7,291,254 - Nov. 6, 2007 | Substrates” |
| 10/830,262 - Apr. 21, 2004 | Cohen, “Methods of Reducing Interlayer Discontinuities in |
| 2004-0251142 - Dec. 16, 2004 | Electrochemically Fabricated Three-Dimensional |
| 7,198,704 - Apr. 3, 2007 | Structures” |
| 10/841,100 - May 7, 2004 | Cohen, “Electrochemical Fabrication Methods Including |
| 2005-0032362 - Feb. 10, 2005 | Use of Surface Treatments to Reduce Overplating and/or |
| 7,109,118 - Sep. 19, 2006 | Planarization During Formation of Multi-layer Three- |
| | Dimensional Structures” |
| 10/841,347 - May 7, 2004 | Cohen, “Multi-step Release Method for Electrochemically |
| 2005-0072681 - Apr. 7, 2005 | Fabricated Structures” |
| — | |
| 10/949,744 - Sep. 24, 2004 | Lockard, “Multi-Layer Three-Dimensional Structures |
| 2005-0126916 - Jun. 16, 2005 | Having Features Smaller Than a Minimum Feature Size |
| 7,498,714 - Mar. 3, 2009 | Associated with the Formation of Individual Layers” |
| 12/345,624 - Dec. 29, 2008 | Cohen, “Electrochemical Fabrication Method Including |
| — | Elastic Joining of Structures” |
| 8,070,931 - Dec. 6, 2011 | |
| 14/194,564 - Feb. 28, 2014 | Kumar, “Methods of Forming Three-Dimensional |
| 2014-0238865 - Aug. 28, 2014 | Structures Having Reduced Stress and/or Curvature” |
| 9,540,233 - Jan. 10, 2017 | |
| 14/720,719 - May 22, 2015 | Veeramani, “Methods of Forming Parts Using Laser |
| — | Machining” |
| 9,878,401 - Jan. 30, 2018 | |
| 14/872,033 - Sep. 30, 2015 | Le, “Multi-Layer, Multi-Material Microscale and Millimeter |
| — | Scale Batch Part Fabrication Methods Including |
| — | Disambiguation of Good Parts and Defective Parts” |

Though various portions of this specification have been provided with headers, it is not intended that the headers be used to limit the application of teachings found in one portion of the specification from applying to other portions of the specification. For example, alternatives acknowledged in association with one embodiment, are intended to apply to all embodiments to the extent that the features of the different embodiments make such applications functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements from other embodiments or aspects set forth herein for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective independent or dependent claims should they be written.

In view of the teachings herein, many further embodiments, alternatives in design and uses of the embodiments of the instant invention will be apparent to those of skill in the art. As such, it is not intended that the invention be limited to the illustrative embodiments, alternatives, and uses described above but instead that it be solely limited by the claims presented hereafter.

1. A method of forming a probe array, comprising:
(a) forming an array preform comprising:
(i) providing a build substrate;
(ii) forming at least portions of a plurality of probe preforms using a multi-layer, multi-material fabrication process with a first layer being formed directly or indirectly on the build substrate, wherein each of the preforms include at least one spring region;
(b) engaging at least one deformation tool with the probe preforms of the array preform; and
(c) transforming the probe preforms using the at least one deformation tool to longitudinally and plasticly deform the at least one spring region of the preforms to extend the length of the preforms while in an array configuration.

2. The method of claim 1 wherein the method additionally comprises a lateral plastic deformation of the spring regions of the preforms as well as the longitudinal deformation.

3. The method of claim 2 wherein at least a portion of the lateral and longitudinal deformations occur in a manner selected from the group consisting of: (1) as simultaneous deformations, (2) as series deformations, (3) in a plurality of alternating longitudinal and lateral deformations, (4) setting deformation movement after compensating for elastic spring back before at least some deformations to better match actual deformation to a targeted deformation level or position, and (5) measuring an actual amount of plastic deformation or position and comparing it to a targeted amount and performing additional deformation if the measured amount is not within a defined tolerance of the targeted amount.

4. The method of claim 1 where the preforms are assigned to groups and deformation occurs in a series of movements on a group-by-group basis.

5. The method of claim 4 wherein the basis is selected from the group consisting of: (1) deformation of one group after deformation of another; (2) deformation of one group and deformation of another group where only a portion of the deformation occur simultaneously, (3) deformation of groups simultaneously but using different amounts of motion; (4) multi-step deformation of one group along with single step deformation of another, (5) multi-step deformation of one group along with single step deformation of another wherein the none of the deformation occurs simultaneously, (6) multi-step deformation of one group along with single step deformation of another wherein single step deformation occurs simultaneous with one of the multi-step deformations; (7) multi-step deformation of one group along with multi-step deformation of another group wherein none of the deformations occur simultaneously, (8) multi-step deformation of one group along with multi-step deformation of another group wherein a portion of the deformation occur simultaneously; (9) multi-step deformation of one group along with multi-step deformation of another group wherein at least some of the deformations have different amounts of motions; and (10) wherein a different amount of spring back is compensated for in deformation one group versus another group.

6. The method of claim 1 wherein the spring region of each of a plurality of probe preforms comprises at least one spring element selected from the group consisting of: (1) a single laterally configured planar spring element, (2) a plurality of laterally configured planar spring elements connected by longitudinally oriented bridge elements, (3) at least one multi-step region comprising a plurality of laterally offset elements stacked directly or indirectly on other laterally offset elements, (4) at least one multi-step region comprising a plurality of laterally offset elements stacked directly or indirectly on other laterally offset elements wherein the laterally offset elements are elongated elements.

7. The method claim 1 wherein at least some preforms have portions that laterally overlay or underlay portions of adjacent probes wherein the overlaying or underlaying portions are longitudinally offset from each other.

8. The method of claim 7 where upon deformation the overlaying or underlaying lateral portions of adjacent probes do not contact one another.

9. The method of claim 7 where upon deformation the overlaying or underlaying lateral portions contact but slide past one another such that, when in a final extended state and in an operation state, adjacent probes do not come into direct physical contact.

10. The method of claim 1 wherein the build structure functions as an array substrate when the array is in use.

11. The method of claim 1 wherein the build substrate is removed from the probe array or preform array prior to putting the probe array to use.

12. The method of claim 11 wherein an array substrate is attached to the probe preforms or probes at a time selected from the group consisting of: (1) prior to putting the probe array into use, (2) prior to transforming the probe preforms, (3) after at least partially transforming the probe preforms, and (4) after completely transforming the probe preforms.

13. The method of claim 1 wherein the method of forming the probe array additionally comprises engaging at least one guide plate with the probe preforms or probes.

14. The method of claim 1 wherein the multi-layer, multi-material fabrication process comprises forming a plurality of multi-material layers representing at least portions of cross-sections of the plurality of probe preforms, wherein each successive layer formed is formed on and adhered to an immediately preceding layer wherein each of at least a portion of the plurality of layers comprises at least two materials with at least one being a structural material and with at least one being a sacrificial material, wherein the formation of each such multi-material layer comprises:
(A) depositing a first of the at least two materials;
(B) depositing a second of the at least two materials,
(C) planarizing a plurality of the at least two materials.

15. The method of claim 1 wherein the preforms comprise one or more planar elements (e.g. spiral, straight, bent, or meandering structures) that undergo longitudinal extension to obtain a probe height that is greater than a preform height when not under an external load.

16. The method of claim 15 wherein the preforms also undergo longitudinal and/or lateral extension to provide the probes with desired X and Y end locations when not under an external load.

17. A probe array, comprising:
(a) a plurality of probes; and
(b) at least one probe retention structure for holding the probes in an array configuration,
wherein individual probes have stair-stepped surface configurations with stair-steps having at least two different orientations on at least two different portions of individual probes.

18. The probe array of claim 17 wherein the at least two different orientations and portions are at least three different orientations and three different portions.
